(19) United States
(12) Patent Application Publication
(10) Pub. No.: US 2025/0125819 A1
(43) Pub. Date: Apr. 17, 2025

(54) ENERGY-EFFICIENT DATAPATH FOR VECTOR-SCALED HIERARCHICAL CODEBOOK QUANTIZATION

(71) Applicant: NVIDIA Corporation, Santa Clara, CA (US)

(72) Inventors: Rangharajan Venkatesan, San Jose, CA (US); Reena Elangovan, Milpitas, CA (US); Brucek Kurdo Khailany, Austin, TX (US); Brian Matthew Zimmer, Sunnyvale, CA (US)

(21) Appl. No.: 18/985,581

(22) Filed: Dec. 18, 2024

Related U.S. Application Data
(63) Continuation-in-part of application No. 18/731,069, filed on May 31, 2024.
(63) Continuation-in-part of application No. 17/086,114, filed on Oct. 30, 2020.
(60) Provisional application No. 63/608,102, filed on Dec. 8, 2023.
(60) Provisional application No. 63/071,949, filed on Aug. 28, 2020.
(60) Provisional application No. 63/089,889, filed on Oct. 9, 2020.

(51) Int. Cl. H03M 13/09; H03M 13/00

(52) U.S. Cl. CPC H03M 13/091; H03M 13/6577

(57) ABSTRACT

Vector-scaled hierarchical codebook quantization reduces precision (bitwidth) vectors of parameters and may enable energy-efficient acceleration of deep neural networks. A vector (block array) comprises one or more parameters within a single dimension of a multi-dimensional tensor (or kernel). For example, block array comprises 4 sub-vectors (blocks) and each sub-vector comprises 8 parameters. The parameters may be represented in integer, floating-point, or any other suitable format. A vector cluster quantization technique is used to quantize blocks of parameters in real-time. Hardware circuitry within a datapath identifies an optimal codebook of a plurality of codebooks for quantizing each block of parameters and the block is encoded using the identified codebook. During processing, the identified codebook is used to obtain the quantized parameter and perform computations at the reduced precision.

### CLAIM OF PRIORITY

This application is a continuation-in-part of U.S. application Ser. No. 18/731,069 (Attorney Docket No. 514616) titled “Vector Clustered Quantization,” filed May 31, 2024 which claims the benefit of U.S. Provisional Application No. 63/608, 102 (Attorney Docket No. 23-SC-1131-US01) titled “OPTIMAL VECTOR CLUSTERED QUANTIZATION FOR NN INFERENCE,” filed Dec. 8, 2023, the entire contents of which is incorporated herein by reference. This application is a continuation-in-part of U.S. application Ser. No. 17/086,114 (Attorney Docket No. 513223) titled “Fine-Grained Per-Vector Scaling for Neural Network Quantization,” filed Oct. 30, 2020 which claims the benefit of U.S. Provisional Application No. 63/071,949 (Attorney Docket No. 513216) titled “Fine-Grained Per-Vector Scaling for Neural Network Quantization,” filed Aug. 28, 2020 and U.S. Provisional Application No. 63/089,889 (Attorney Docket No. 513263) titled “Fine-Grained Per-Vector Scaling for Neural Network Quantization,” filed Oct. 9, 2020, the entire contents of both are incorporated herein by reference.

### BACKGROUND

Neural network models have achieved remarkable results in several natural language processing and generative artificial intelligence (AI) tasks, sparking an increasing interest in high performance neural network inference. However, with the ever-growing model-size of neural network models, such as large language models (LLMs), large compute and memory overheads limit inference performance. Quantization of neural network models is a promising technique to alleviate such demands. In particular, post-training quantization (PTQ) of neural network models is highly desirable for preserving model generalization.

Fine-grained quantization at per-vector granularity has emerged as an effective technique for sub-8-bit quantization of LLMs. Recent per-vector quantization efforts have focused on improving inference accuracy through the design of novel number formats. However, for a given bit-width, there is no known guarantee for best possible accuracy. There is a need for addressing these issues and/or other issues associated with the prior art.

### SUMMARY

Embodiments of the present disclosure relate to vector clustered quantization and an energy-efficient datapath for vector-scaled hierarchical codebook quantization. Systems and methods are disclosed for vector quantization for processing by a neural network. Vector clustered quantization reduces precision (bitwidth) of vectors and may enable energy-efficient acceleration of deep neural networks. A vector comprises one or more parameters (elements, scalars, or values) within a single dimension of a multi-dimensional tensor (or kernel). The memory footprint of the neural network model is reduced when the parameters (e.g., weights and/or activations) for the trained model are quantized. The parameters may be represented in integer, floating-point, or any other suitable format. Quantization reduces the number of bits (e.g., resolution) used to represent a value, where decreasing the number of bits used can decrease the accuracy of computations that use the value.

Conventional fine-grained quantization methods rely on using number formats at various granularities (i.e., number formats for fine-grained scale factors or for per-element values). Vector clustered quantization achieves a local minima of per-vector quantization error for LLMs. Vector clustered quantization is an iterative vector-clustering based quantization method where during each iteration, the vectors are clustered into vector-clusters and each vector-cluster is individually quantized such that the quantization error is minimized. Vector clustered quantization advances the pareto-optimal bitwidth-vs-perplexity compared to the conventional solutions. In an embodiment, vector clustered quantization achieves a local minima of per-vector quantization error measured using mean squared error (MSE). In contrast to conventional systems, such as those described above, the vector clustered quantization technique minimizes quantization noise for fine-grained quantization. Furthermore, some conventional vector quantization techniques map a vector to a codebook. In contrast, in an embodiment, vector clustered quantization performs a two-level encoding where a vector is first mapped to a codebook and then each scalar (block or sub-vector) within the vector is mapped to an entry within the codebook that stores a value that best matches the scalar.

The parameters are normalized according to a scale factor. A set of quantizers is initialized for a first step (vector-clustering). In an embodiment, the quantizers are codebooks (e.g., lookup tables). After initialization, in an embodiment, the normalized parameters in each block (at least a portion of a vector) are quantized using the set of quantizers to produce quantized vectors. In an embodiment, blocks are mapped into clusters based on quantization errors computed for the quantized blocks. Each block is mapped to the quantizer that achieves least quantization error and is included in a cluster associated with the quantizer. The normalized parameters in the block are encoded using the quantizer to which the block is mapped. Multiple blocks comprise a block array (vector) and each block array is associated with a single scale factor that is shared by the blocks in the block array.

In an embodiment, a system for processing parameters comprises a memory and a processor that is coupled to the memory. The memory stores a block array including the parameters organized into blocks, each block including a subset of the parameters. The processor encodes the block array by normalizing the parameters using a scale factor for the block array and, for each block, each normalized parameter in the block is mapped to quantized values stored in each codebook of a plurality of codebooks to determine a set of quantization errors, where each quantization error in the set of quantization errors is associated with a different one of the codebooks in the plurality of codebooks. For each block, the codebook in the plurality of codebooks that is associated with a minimum quantization error in the set of quantization errors for the block is identified as a selected codebook for the block and the normalized parameters in each block are encoded to a bitwidth using the selected codebook for the block to produce an encoded block array. In an embodiment, the bitwidth equals a bitwidth of indices corresponding to entries of the selected codebook that stores quantized versions of the subset of parameters in the encoded version.

### BRIEF DESCRIPTION OF THE DRAWINGS

The present systems and methods for an energy-efficient datapath for vector-scaled hierarchical codebook quantization are described in detail below with reference to the attached drawing figures, wherein:

FIG. 1A is a conceptual diagram illustrating per-vector scaling for convolution computations, suitable for use in implementing some embodiments of the present disclosure.

FIG. 1B is a conceptual diagram illustrating mapping vectors of parameters to clusters, suitable for use in implementing some embodiments of the present disclosure.

FIG. 1C is a conceptual diagram illustrating associating clusters of vectors with quantizers, suitable for use in implementing some embodiments of the present disclosure.

FIG. 2A illustrates a block diagram of an example vector clustered quantization system suitable for use in implementing some embodiments of the present disclosure.

FIG. 2B is a conceptual diagram illustrating a vector associated with a quantizer and indices, suitable for use in implementing some embodiments of the present disclosure.

FIG. 2C illustrates graphs of quantized vector clusters, in accordance with an embodiment.

FIG. 2D illustrates a flowchart of a method for vector clustered quantization suitable for use in implementing some embodiments of the present disclosure.

FIG. 3A is a conceptual diagram illustrating a block array of four blocks that are each associated with a codebook and indices, suitable for use in implementing some embodiments of the present disclosure.

FIG. 3B illustrates a block diagram of an example block cluster quantization unit suitable for use in implementing some embodiments of the present disclosure.

FIG. 3C illustrates a flowchart of a method for processing parameters, in accordance with an embodiment.

FIG. 3D illustrates a block diagram of an example processing element suitable for use in implementing some embodiments of the present disclosure.

FIG. 4 illustrates an example parallel processing unit suitable for use in implementing some embodiments of the present disclosure.

FIG. 5A is a conceptual diagram of a processing system implemented using the PPU of FIG. 4, suitable for use in implementing some embodiments of the present disclosure.

FIG. 5B illustrates an exemplary system in which the various architecture and/or functionality of the various previous embodiments may be implemented.

FIG. 5C illustrates components of an exemplary system that can be used to train and utilize machine learning, in at least one embodiment.

FIG. 6 illustrates an exemplary streaming system suitable for use in implementing some embodiments of the present disclosure.

### DETAILED DESCRIPTION

Systems and methods are disclosed related to an energy-efficient datapath for vector-scaled hierarchical codebook quantization. Quantization reduces precision (bitwidth) of vectors and may enable energy-efficient acceleration of deep neural networks. A vector comprises one or more parameters (elements, scalars, or values) within a single dimension of a multi-dimensional tensor (matrix or kernel). The memory footprint of the neural network model is reduced when the parameters (e.g., weights and/or activations) for the trained model are quantized. The parameters may be represented in integer, floating-point, or any other suitable format of any number of bits. Quantized weights and/or activation values are inputs to dot product computations performed by a layer of a neural network. For example, a (quantized) vector includes V elements and each element is a B-bit integer. In an embodiment, each quantized element is an index used to access a number (quantization level) stored in a look-up table.

Matrix operations performed by the neural networks require many multiplication calculations, so reducing the number of bits that are multiplied may reduce the energy that is consumed. In an embodiment, weight-activation products are computed and summed to produce vector dot products that are accumulated to compute elements of a multi-dimensional output tensor. The elements of the output tensor are input activations to a subsequent layer of the neural network. Quantizing the elements of the output tensor (activations) reduces the memory footprint needed to store the output tensor and reduces the bandwidth consumed to transmit the output tensor. Similarly, quantizing weights reduces the memory footprint needed to store the weights and reduces the bandwidth consumed to transmit the weights. Quantizing smaller sets of the parameters, such as each vector, using a shared scale factor improves accuracy compared with quantizing larger sets of the parameters. Accuracy of the calculations may be maintained by quantizing and scaling the parameters using fine-grained per-vector scale factors.

In contrast to conventional systems, such as those described above, the vector clustered quantization technique mitigates accuracy loss typical in existing quantized deep neural network (DNN) models. To reduce quantization-related accuracy loss, a separate scale factor may be used for a number of elements (e.g., 16-64) within a single dimension of a tensor. To achieve an efficient hardware implementation, the per-vector scale factors can be implemented with low-bitwidth integer or floating-point format values. Per-vector scaling may achieve better inference accuracy at low precision compared to conventional scaling techniques for neural networks. Additionally, in an embodiment, neither retraining nor quantization-aware training is not required to use the vector clustered quantization technique.

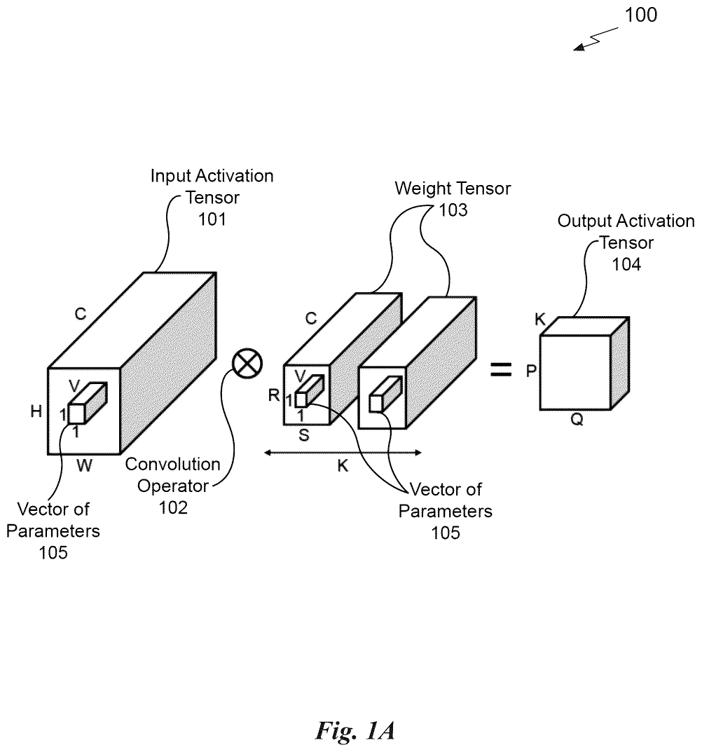

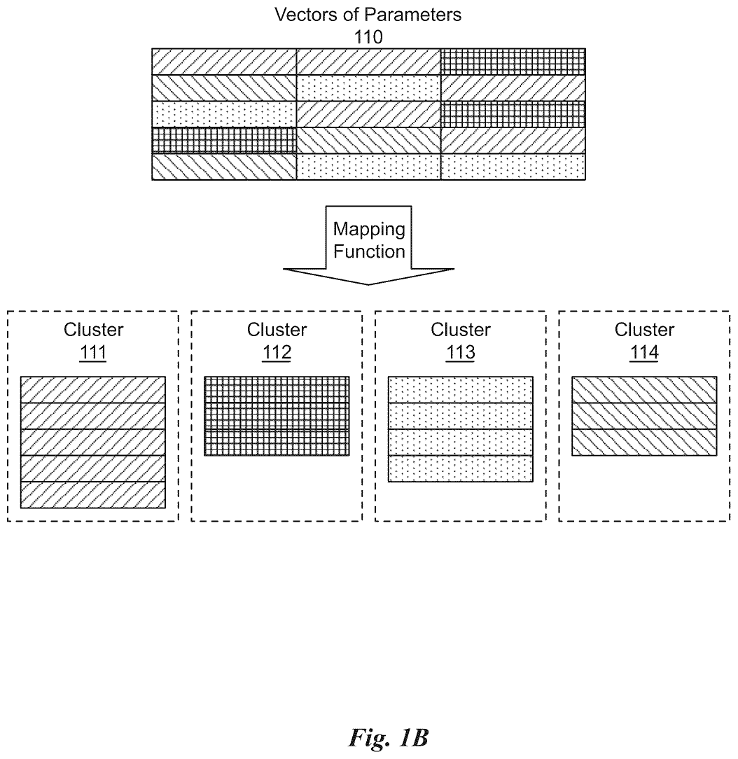

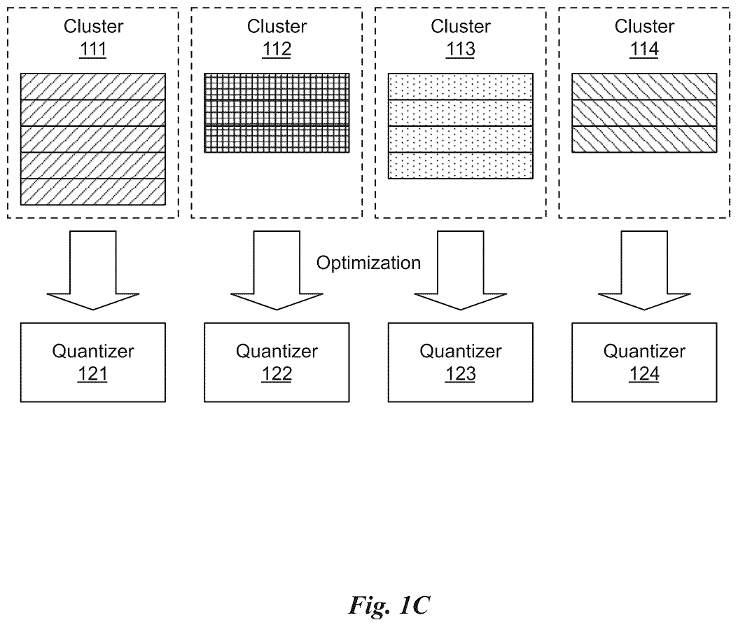

FIG. 1A is a conceptual diagram 100 illustrating per-vector parameters that may be scaled for convolution computations, suitable for use in implementing some embodiments of the present disclosure. A convolution operator 102 applies K kernels (C×R×S) of a weight tensor 103 to an input activation tensor 101 (C×H×W) to produce an output activation tensor 104.

Quantization scales high-precision values of a particular range to lower-precision values of a different range. For mapping a high-precision number x to a lower-precision number,

$${x}_{q} , {x}_{q} = Q ( \frac{x}{s} , N )$$

where s is the scale factor and Q(a, b) is the function that quantizes a to a b-bit integer. Therefore, scale factors play an important role in determining the quantization error which affects the ultimate accuracy of the quantized neural network model. Conventionally, to avoid overloading the quantized neural network model with too many scale factors and nullifying the compute and memory benefits of quantization, scale factors are shared among multiple tensor elements.

Typically, scale factors are shared at a coarse granularity by elements of an entire tensor or a large sub-tensor. For example, conventionally, a single scale factor may be used for the entire input activation tensor 101 and another scale factor may be used for each kernel of the weight tensor 103. While coarse-grained scaling amortizes the cost of scaling across many elements, it likely requires mapping a broader range of values to the specified low-precision representation. The resulting increase in quantization error introduces significant accuracy loss for low-precision representations. The problem is exacerbated for DNNs whose input activations and/or weight values span a wide dynamic range.

Rather than using a single scale factor for an entire tensor or kernel, quantization may instead be performed using fine-grained per-vector scale factors to mitigate quantization-related accuracy loss. In contrast to coarse-grained per-layer/per-output-channel scaling, per-vector quantization employs a scale factor for each vector of parameters 105 (V×1×1) in the input activation tensor 101 and/or weight tensor 103 as shown in FIG. 1A. The vector size V determines the number of elements (e.g., parameter values) that are included in each vector of parameters 105. Each vector of parameters 105 includes V elements in a single dimension of the multi-dimensional parameter tensors. As shown in FIG. 1A, the vector of parameters 105 are in the dimension C. Specifically, the elements in the vector of parameters 105 for the input activation tensor 101 each share the same position (e.g., coordinate) in the H and W dimensions, so that only the position in the C dimension varies for each element. In another embodiment, the vector of parameters 105 includes elements in a different dimension of the multi-dimensional parameter tensors. When the Vis less than the number of elements in the single dimension, the parameter values in the single dimension are separated into multiple vectors and a separate per-vector scale factor is associated with each one of the multiple vectors.

The finer granularity at the vector level allows more precise scale factors to be determined based on local distribution of tensor parameter values in each vector of parameters 105. More precise scaling reduces quantization error and decreases the need for a sophisticated algorithm to compute the scale factors. Moreover, in an embodiment, the unit (V) of a vector matches the unit of vector multiply-accumulate (MAC) hardware circuitry in a DNN accelerator. Such hardware-software synergy based on the vector size leads to an elegant extension of current accelerator architecture for implementing per-vector scaling with low overhead.

In an embodiment, the vectors are quantized using vector cluster quantization. The vectors are each normalized using the absolute maximum value of the parameters in the vector. The normalized vectors are mapped into clusters based on quantization errors. In an embodiment, the normalized vectors are mapped into clusters based on (calibrated) per-vector (max, min) pairs. In an embodiment, the vectors in a cluster are observed to have similar value distributions. A first step (vector-clustering) is completed when each vector is mapped to one of the clusters and each cluster is associated with one of the quantizers in a set of quantizers, so the vectors are effectively mapped or assigned to the quantizers. In a second step, the set of quantizers is optimized and updated based on computed per-cluster quantization errors. The steps may be repeated to jointly optimize the vector-clustering and the per-cluster quantization until a criterion is satisfied (convergence to a local minimum, a fixed number of iterations, etc.). After the second step, the set of quantizers quantizes the parameters within each vector in the cluster associated with the quantizer to produce the quantized vectors.

More illustrative information will now be set forth regarding various optional architectures and features with which the foregoing framework may be implemented, per the desires of the user. It should be strongly noted that the following information is set forth for illustrative purposes and should not be construed as limiting in any manner. Any of the following features may be optionally incorporated with or without the exclusion of other features described.

An n-bit signed integer (INT) can be represented in 2s-complement or sign-magnitude format, where the most significant bit denotes the sign in both cases. An n-bit signed floating-point (FP) scalar x comprises of a 1-bit sign xₛ, Bₘ-bit mantissa (xₘ) and Bₑ,-bit exponent (xₑ) such that Bₘ+Bₑ=n−1. The associated constant exponent bias (E_{bias}) is computed as (2^{B}^{ₑ}⁻¹). In the context of the following description, this format is denoted as E_{B}_{ₑ}M_{B}_{ₘ} and its magnitude is computed as shown in Table I below. In an embodiment, special representations for Inf(±∞) and NaN are discarded to fully utilize the available bit-width. However, a redundant representation for −0 may be considered to maintain symmetry.

TABLE I
magnitude of a floating-point number

| Case | Magnitude | Type |
|---|---|---|
| xₘ = 0, xₑ = 0 | 0 | Zero |
| xₘ > 0, xₑ = 0 | xₛ\| * 0.xₘ * 2(^{x}^{ₑ}^{-E}^{_{bias}}) | Subnormal |
| xₑ > 0 | xₛ * 1.xₘ * 2(^{x}^{ₑ}^{-E}^{_{bias}}) | Normal |

In the context of the following description, the vector clustered quantization method is presented with FP formats as an example. Given an unquantized operand X and an FP format E_{B}_{ₑ}M_{B}_{ₘ}, quantization of X is performed as follows. First, the quantization scale-factor s_{X} that maps the maximum absolute value of X to the maximum quantization level of the E_{Br}M_{Btn} format is computed as:

$${s}_{X} = \frac{max ( \vert X \vert )}{max ( {E}_{{B}_{e}} {M}_{{B}_{m}} )} \qquad Eq . ( 1 )$$

where |⋅| denotes the absolute value function.

Then, X is scaled by s_{X} and quantized to \hat{X} by rounding to the nearest quantization level of E_{B}_{ₑ}M_{B}_{ₘ} as:

$$\hat{X} = round ‐ to ‐ nearest ( \frac{X}{{s}_{X}} , {E}_{{B}_{e}} {M}_{{B}_{m}} ) \qquad Eq . ( 2 )$$

During max-scaled quantization, the scale factor s for activations may be computed dynamically during inference. Vector-wise quantization may be performed similar to tensor-wise quantization described in Equations (1) and (2), where a scale factor s, is required for each vector ν that maps the maximum absolute value of the vector to the maximum quantization level. While smaller vector lengths can lead to larger accuracy gains, the associated memory and computational overheads due to the per-vector scale factors increases. To alleviate such overheads, a second-level quantization of the per-vector scale factors may be performed.

FIG. 1B is a conceptual diagram illustrating mapping vectors of parameters 110 to clusters 111, 112, 113, and 114, suitable for use in implementing some embodiments of the present disclosure. As shown, for a given L_{ν}, N_{q}, B and quantizers {Qᵢ}ᵢ₌₁^{N}^{_{q}}, the vectors of parameters 110 of length L_{ν} are first clustered into N_{q} clusters 111, 112, 113, and 114 and each vector-cluster is individually quantized by a B-bit quantizer associated with the cluster, as illustrated in FIG. 1C.

Vector clustered quantization is formulated as follows. Given an operand X composed of N_{X} scalar elements (parameters), a vector-wise decomposition is denoted as {νᵢ}ᵢ₌₁^{N}^{_{ν}}, where each νᵢ is a vector of L_{ν} consecutive elements in X, and

$${N}_{v} = \frac{{N}_{X}}{{L}_{v}} .$$

Vector-clustered quantization uses a family of N_{q} quantizers {Qᵢ}ᵢ₌₁^{N}^{_{q}}, where each Qᵢ is a B-bit quantizer, and a mapping function f: {1 . . . N_{ν}}→{1 . . . N_{q}} clusters the vectors of parameters 110 into the N_{q} clusters 111, 112, 113, and 114. A result of vector-clustered quantization of a given vector ν in X, denoted as \hat{ν}, is obtained as:

$$\hat{v} = {Q}_{f ( v )} ( v ) \qquad Eq . ( 3 )$$

Thus, as shown in equation (3), vector-clustered quantization is a two step process where first, the mapping function is invoked to assign each vector in the vectors of parameters 110 to one of the clusters 111, 112, 113, and 114. In an embodiment, the vectors in each cluster have similar value distributions. In an embodiment, each of the N_{q} clusters 111, 112, 113, and 114 is associated with a respective cluster index. During the second step, the quantizer corresponding to a particular cluster index (associated with the cluster) is updated to optimally quantize the parameters in the vectors of parameters 110 that are mapped to the cluster. In contrast with conventional vector quantization techniques, vector clustered quantization explores optimal vector clustering in addition to per-vector quantization for minimizing quantization MSE.

FIG. 1C is a conceptual diagram illustrating associating the clusters 111, 112, 113, and 114 of the vectors of parameters 110 with quantizers 121, 122, 123, and 124, suitable for use in implementing some embodiments of the present disclosure. In an embodiment, the vectors of parameters 110 are first mapped into the clusters 111, 112, 113, and 114 based on quantization errors. In an embodiment, the vectors of parameters 110 are first mapped into the clusters 111, 112, 113, and 114 based on initialization data comprising (calibrated) per-vector statistical proxies corresponding to quantization error. A first step (vector-clustering) is completed when each vector of parameters 110 is mapped to one of the clusters 111, 112, 113, and 114. Each one of the one of the clusters 111, 112, 113, and 114 is associated with a respective one of the quantizers 121, 122, 123, and 124 in a set of quantizers, so that a one-to-one mapping or assignment is accomplished between the vectors of parameters 110 and the quantizers 121, 122, 123, and 124. In a second step (per-cluster quantization), the set of quantizers 121, 122, 123, and 124 is optimized based on computed per-cluster quantization errors. In an embodiment, optimization of a quantizer minimizes the MSE for quantizing the vectors in the cluster associated with the quantizer. In an embodiment, the Lloyd-Max algorithm is used to optimize each quantizer. The vector clusters are unchanged (fixed) during the second step, just as the quantizers are not modified during the first step. The steps may be repeated until a criterion is satisfied. Following one or more iterations, after the second step, the set of quantizers 121, 122, 123, and 124 quantizes the parameters within each vector in the cluster 111, 112, 113, and 114 associated with the quantizer to produce the quantized vectors.

The set of quantizers is initialized for the first step (vector-clustering). In an embodiment, the quantizers 121, 122, 123, and 124 are randomly initialized. In an embodiment, the quantizers 121, 122, 123, and 124 are initialized to optimally quantize one of the vectors. In an embodiment, the quantizers 121, 122, 123, and 124 are initialized according to a centroid-based or statistical proxy-based calibration. In an embodiment, the parameters in the vectors of parameters 110 are normalized before the first step. In an embodiment, the set of quantizers includes at least two quantizers. After initialization, the first step is initiated.

In an embodiment, to perform the mapping, the parameters of each vector of parameters 110 is quantized by each one of the quantizers 121, 122, 123, and 124 in the set to produce quantized vectors. An MSE is computed for each quantized vector and each quantized vector is assigned or mapped to the quantizer that produces the minimum MSE for the vector. The vectors assigned to a particular quantizer are included in a cluster that is associated with the quantizer. As shown in FIGS. 1B and 1C, each vector of parameters 110 is mapped to one of the clusters 121, 122, 123, and 124 and each cluster is associated one of the quantizers 121, 122, 123, and 124 in the set so the vectors of parameters 110 are mapped or assigned to the quantizers 121, 122, 123, and 124.

A goal of vector-clustered quantization is to construct a set of quantizers Q resulting in minimal quantization MSE [symbol] [∥ν−\hat{ν}∥²]. In an embodiment, for vector clustering, the following mapping function for minimizing quantization errors may be used:

$$f ( v ) = {arg min}_{i = 1 … {N}_{q}} 𝔼 [ {‖ v - {Q}_{i} ( v ) ‖}^{2} ] \qquad Eq . ( 4 )$$

Therefore, each vector is mapped to the cluster that is associated with the quantizer that yields lowest MSE. In order to construct Q, the two step iterative algorithm may be employed with each iteration executing the first vector-clustering step, and the second quantizer updating step. Specifically, at iteration n, N_{q} vector clusters

$${v}^{( n )} = {\{ {v}_{i}^{( n )} \}}_{i = 1}^{{N}_{q}}$$

are constructed where each cluster is defined as:

$${V}_{i}^{( n )} = \{ {v}_{j} \vert {f}^{( n )} ( {v}_{j} ) = i for j ∈ \{ 1 … {N}_{v} \} \} \qquad Eq . ( 5 )$$

As shown, the mapping function uses quantizers from the previous iteration, i.e.,

$${f}^{( n )} ( v ) = {arg min}_{i = 1 … {N}_{q}} 𝔼 [ {‖ v - {Q}_{i}^{( n )} ( v ) ‖}^{2} ] \qquad Eq . ( 6 )$$

Thus, in the vector-clustering step, vectors are assigned so as to minimize local quantization MSE over the available candidate quantizers at that iteration. Then, in the second step, the quantizers are optimized and updated as:

$${Q}_{i}^{( n )} ← {Q}_{LloydMax} ( {V}_{i}^{( n )} , B ) \qquad Eq . ( 7 )$$

where the Lloyd-Max algorithm described in the following paragraphs and equation (8) is invoked on the data of the corresponding cluster [symbol] .

For a given quantization bit-width B and an operand X, the Lloyd-Max algorithm finds 2^{B} quantization levels

$${\{ {\hat{x}}_{i} \}}_{i = 1}^{{2}^{B}}$$

such that quantizing X by rounding each scalar x∈X to the nearest quantization level minimizes the quantization MSE. The Lloyd-Max algorithm starts with initialized quantization levels and then iteratively computes quantization thresholds

$${\{ {τ}_{i} \}}_{i = 1}^{{2}^{B} - 1}$$

and updates quantization levels

$${\{ {\hat{x}}_{i} \}}_{i = 1}^{{2}^{B}} .$$

Specifically, at iteration n, thresholds are set to the midpoints of the previous iteration's levels:

$${τ}_{i}^{( n )} = \frac{{\hat{x}}_{i}^{( n - 1 )} + {\hat{x}}_{i + 1}^{( n - 1 )}}{2} for i = 1 … {2}^{B} - 1$$

And then, the quantization levels are computed as conditional means of the data regions defined by the new thresholds:

$${\hat{x}}_{i}^{( n - 1 )} = 𝔼 [ X \vert X ∈ [ {τ}_{i - 1}^{( n )} , {τ}_{i}^{( n )} ] ] for i = 1 … {2}^{B}$$

where to satisfy boundary conditions τ₀=−∞ and τ₂_{^{B}}=∞. The Lloyd-Max algorithm runs the above recursion until convergence. In the context of the following description, the following notation is used to denote the application of the Lloyd-Max algorithm to a quantizer Q:

$$Q ← {Q}_{LloydMax} ( X , B ) , \qquad Eq . ( 8 )$$

where application of the Lloyd-Max algorithm requires the data X and the number of quantization bits B. Compared with quantizing a layer of weights at per-tensor granularity a 7-bit floating-point (E3M3) quantizer, a 7-bit Lloyd-Max quantizer achieves lower quantization MSE and lower perplexity. However, the perplexity degradation is significant during ultra-low-precision quantization (<6 bits). Fine-grained (per-vector) quantization alleviates the perplexity degradation.

For a given vector νⱼ, the quantization MSE during vector clustered quantization can be empirically evaluated as

$$\frac{1}{{L}_{𝓋}} {‖ {𝓋}_{j} - {\hat{𝓋}}_{j} ‖}_{2}^{2}$$

where \hat{ν}ⱼ is computed from equation (3) as Q_{f(ν}_{ᵢ}₎(νⱼ). Further, for a given vector-cluster [symbol] the per-cluster quantization MSE can be computed as

$$\frac{1}{\vert {𝓋}_{i} \vert} {\sum }_{𝓋 ∈ {𝒱}_{i}} \frac{1}{{L}_{𝓋}} {‖ 𝓋 - {Q}_{i}^{( n )} ( 𝓋 ) ‖}_{2}^{2} .$$

Therefore, at the end of iteration n, the overall quantization MSE J⁽ⁿ⁾ for a given operand X composed of N_{q} vector-clusters can be computed as:

$${J}^{( n )} = \frac{1}{{N}_{q}} {\sum }_{i = 1}^{{N}_{q}} \frac{1}{\vert {𝒱}_{i}^{( n )} \vert} {\sum }_{𝓋 ∈ {𝒱}_{i}^{( n )}} \frac{1}{{L}_{𝓋}} {‖ 𝓋 - {Q}_{i}^{( n )} ( 𝓋 ) ‖}_{2}^{2}$$

Each iteration of vector clustered quantization includes the vector-clustering step during which the quantizers Q are fixed and the vector clusters [symbol] are updated, and per-cluster quantization during which the vector clusters [symbol] are fixed and the quantizers Q are optimized and updated. At the end of iteration n, the quantizers are updated from Q⁽ⁿ⁻¹⁾ to Q⁽ⁿ⁾. However, the mapping of a given vector νⱼ to quantizers Q⁽ⁿ⁾ remains the same as in the first step (vector-clustering), that is, f⁽ⁿ⁾ (νⱼ). At the next iteration, during the vector-clustering step, f⁽ⁿ⁺¹⁾ (νⱼ) finds new mapping of νⱼ to the updated quantizers Q⁽ⁿ⁾ such that the quantization MSE over the candidate quantizers is minimized. Therefore, the following result is obtained for νⱼ:

$$\frac{1}{{L}_{𝓋}} {‖ {𝓋}_{j} - {Q}_{{f}^{( n + 1 )}}^{( n )} ( {𝓋}_{j} ) ‖}_{2}^{2} \leq \frac{1}{{L}_{𝓋}} {‖ {𝓋}_{j} - {Q}_{{f}^{( n )} ( {𝓋}_{j} )}^{( n )} ( {𝓋}_{j} ) ‖}_{2}^{2}$$

That is, quantizing νⱼ at the end of the vector-clustering step of iteration n+1 results in lower quantization MSE compared to quantizing at the end of iteration n. Because the quantization error is reduced for all ν∈X, the following may be asserted:

$${\tilde{J}}^{( n + 1 )} = \frac{1}{{N}_{q}} {\sum }_{i = 1}^{{N}_{q}} \frac{1}{\vert {𝓋}_{i}^{( n + 1 )} \vert} {\sum }_{𝓋 ∈ {𝒱}_{i}^{( n + 1 )}} \frac{1}{{L}_{𝓋}} {‖ 𝓋 - {Q}_{i}^{( n )} ( 𝓋 ) ‖}_{2}^{2} \leq {J}^{( n )} \qquad Eq . ( 9 )$$

where \tilde{J}⁽ⁿ⁺¹⁾ is the quantization MSE after the vector-clustering step at iteration n+1.

Next, during the second step, according to equation (7) at iteration n+1, the per-cluster quantizers Q⁽ⁿ⁾ are updated to Q⁽ⁿ⁺¹⁾ by invoking the Lloyd-Max algorithm. For any given value distribution, the Lloyd-Max algorithm minimizes the quantization MSE. Therefore, for a given vector-cluster [symbol] the following result is obtained:

$$\frac{1}{\vert {𝓋}_{i}^{( n + 1 )} \vert} {\sum }_{𝓋 ∈ {𝒱}_{i}^{( n + 1 )}} \frac{1}{{L}_{𝓋}} {‖ 𝓋 - {Q}_{i}^{( n + 1 )} ( 𝓋 ) ‖}_{2}^{2} \leq \frac{1}{\vert {𝓋}_{i}^{( n + 1 )} \vert} {\sum }_{𝓋 ∈ {𝒱}_{i}^{( n + 1 )}} \frac{1}{{L}_{𝓋}} {‖ 𝓋 - {Q}_{i}^{( n )} ( 𝓋 ) ‖}_{2}^{2} \qquad Eq . ( 10 )$$

More specifically, quantizing the given vector-cluster [symbol] after updating the associated quantizer from Qᵢ⁽ⁿ⁾ to Qᵢ⁽ⁿ⁺¹⁾ results in lower quantization MSE. Because this is true for all the vector clusters, the following result is derived:

$${J}^{( n )} = \frac{1}{{N}_{q}} {\sum }_{i = 1}^{{N}_{q}} \frac{1}{\vert {𝓋}_{i}^{( n + 1 )} \vert} {\sum }_{𝓋 ∈ {𝒱}_{i}^{( n + 1 )}} \frac{1}{{L}_{𝓋}} {‖ 𝓋 - {Q}_{i}^{( n + 1 )} ( 𝓋 ) ‖}_{2}^{2} \leq {\tilde{J}}^{( n + 1 )} \qquad Eq . ( 11 )$$

Following equations (9) and (11), the quantization MSE is non-increasing for each iteration, that is, J⁽¹⁾≥J⁽²⁾≥J⁽³⁾≥ . . . ≥J^{(M)} where M is a maximum number of iterations. Therefore, if the algorithm converges, then it must be that it has converged to a local minimum.

Prior to clustering, normalizing the operand vectors speeds up convergence. For a vector νⱼ a normalization-factor mⱼ is computed as:

$${m}_{j} = {max}_{l = 1 … {L}_{𝓋}} ( \vert {𝓋}_{j} [ l ] \vert )$$

where νⱼ[l] denotes the l^{th} element of vector νⱼ and |⋅| denotes the absolute value function. Now, the normalized vector \tilde{ν}ⱼ is obtained as:

$${\tilde{𝓋}}_{j} = \frac{{𝓋}_{j}}{{m}_{j}} .$$

To reduce the cost of storing the normalization factor mⱼ for each vector νⱼ, a second-level quantization may be performed for the normalization factors.

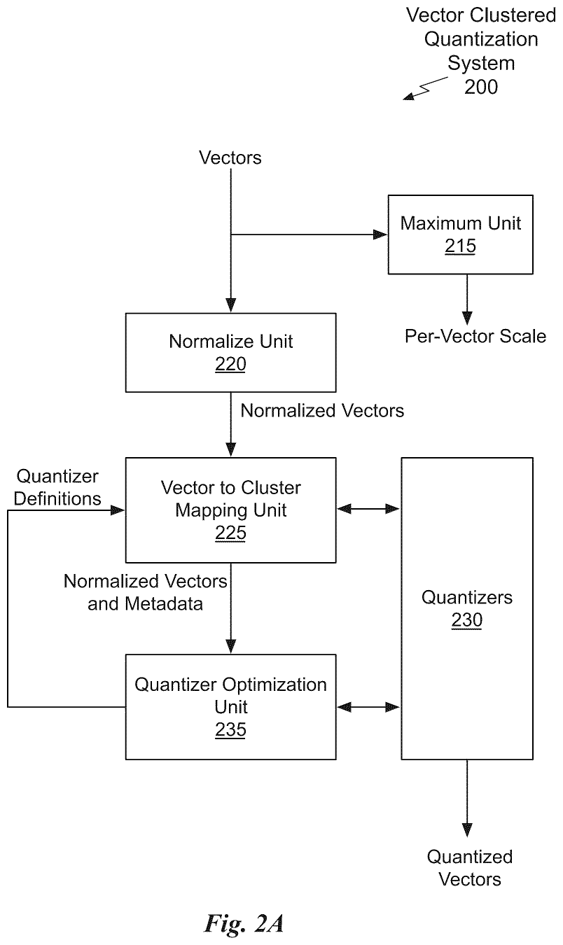

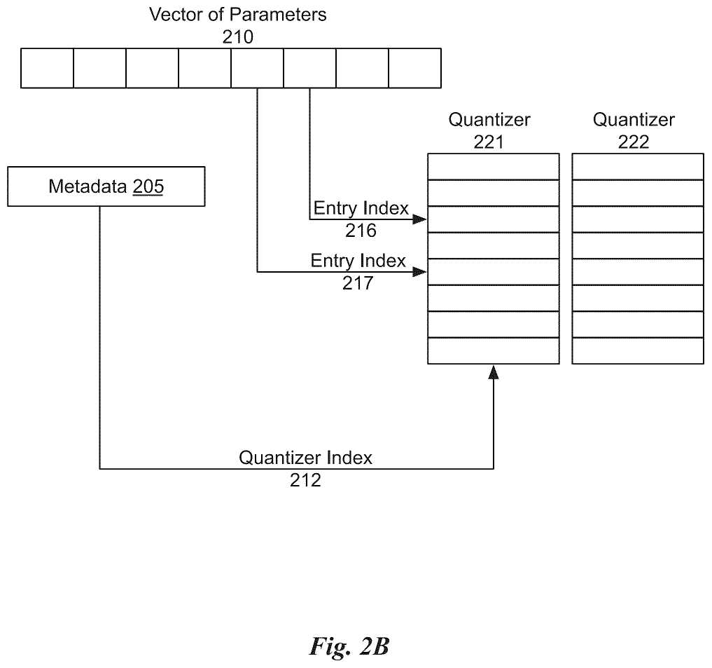

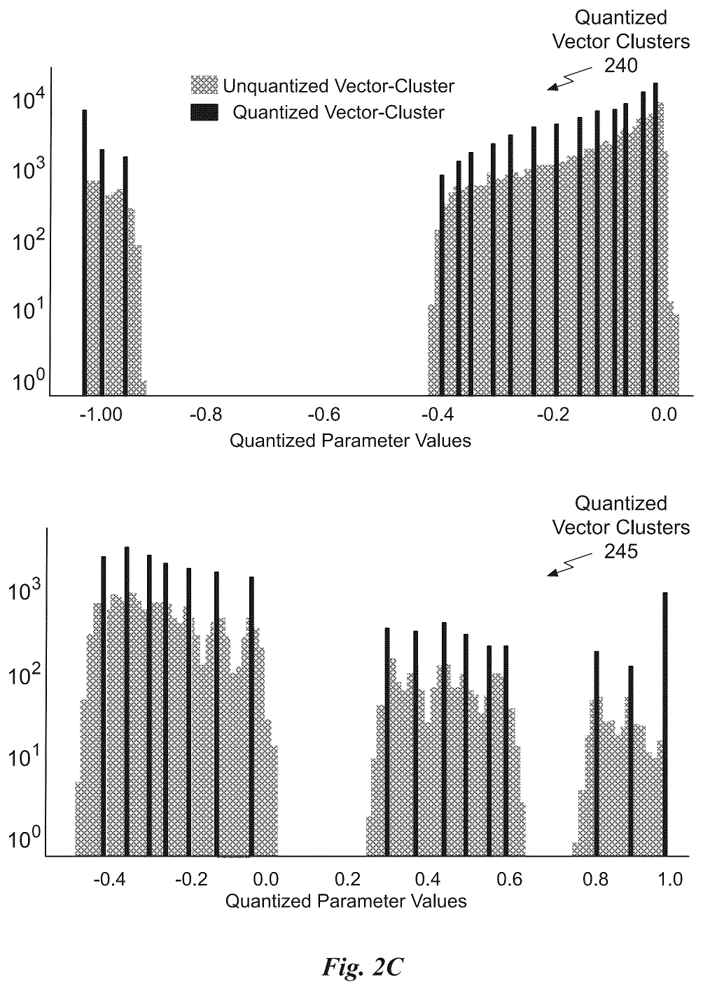

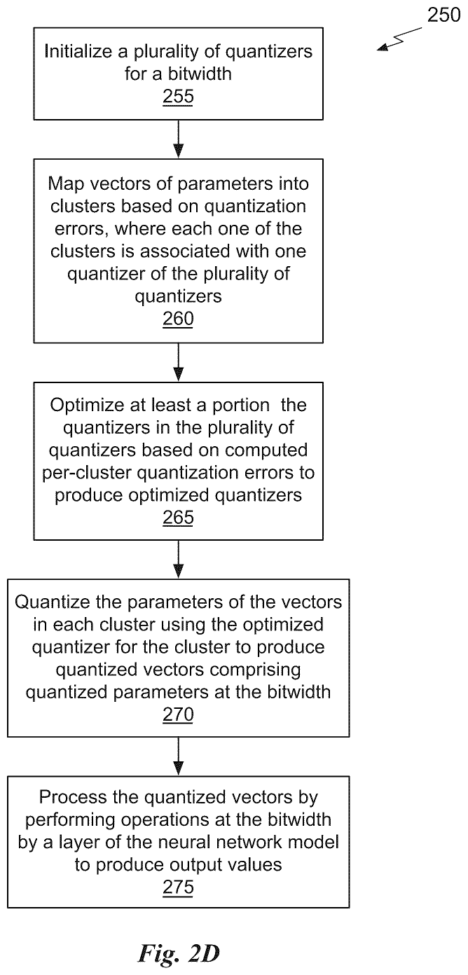

FIG. 2A illustrates a block diagram of an example vector clustered quantization system 200 suitable for use in implementing some embodiments of the present disclosure. The vector clustered quantization system 200 includes a maximum unit 215, a normalize unit 220, a vector to cluster mapping unit 225, a quantizer optimization unit 235, and quantizers 230. The vector clustered quantization system 200 receives the vectors of parameters and generates quantized vectors by iterating one or more times through the two-step quantization process.

It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out by a processor executing instructions stored in memory. Furthermore, persons of ordinary skill in the art will understand that any system that performs the operations of the vector clustered quantization system 200 is within the scope and spirit of embodiments of the present disclosure.

The maximum unit 215, computes the quantization scale-factor s_{X} (per-vector scale) for each vector according to equation (1). The normalize unit 220, receives the vectors νⱼ of length L_{ν} that are extracted from an input tensor X and computes the normalization factors mⱼ and the normalized vectors \tilde{ν}ⱼ. The vector to cluster mapping unit 225, maps the (normalized) vectors to N_{q} clusters based on quantization errors.

The set of quantizers 230 is initialized prior to a first iteration of the first step (vector-clustering) using initialization data. The quantizers 230 may each be initialized to quantize values differently or the same. For subsequent iterations, the quantizers 230 are updated from Q⁽ⁿ⁻¹⁾ to Q⁽ⁿ⁾. In an embodiment, the quantization levels of the quantizers 230 initialized to at least one of random values, calibrated definitions, or precomputed definitions. In an embodiment, the quantizers 230 are initialized according to a centroid-based calibration. In an embodiment, the quantizers 230 are initialized according to statistical proxy-based calibration, where statistical proxies defined for each quantizer correspond to quantization error. In an embodiment, per-vector statistical proxies include one or more of a mean value, an absolute mean value, a median value, an absolute median value, or a pair including a maximum value and minimum value of the parameters in a vector to be quantized.

The vector to cluster mapping unit 225 performs the first step (vector-clustering), mapping the vectors into the clusters based on quantization errors. In an embodiment, the quantization errors are computed as the MSE for each one of the vectors quantized by each different quantizer in the quantizers 230. Each vector is then mapped to a cluster associated with the quantizer 230 that produced the minimal MSE for the vector. In another embodiment, the quantization errors correspond to the per-vector statistical proxies and each vector is mapped to a cluster associated with the quantizer 230 associated with a quantizer statistical proxy definition that best matches the per-vector statistical proxy value.

The quantizer optimization unit 235 receives the vectors and metadata and performs the second step (per-cluster quantization), optimizing each quantizer in the quantizers 230 to quantize the cluster associated with the quantizer. In an embodiment, the quantizer optimization unit 235 applies the Lloyd-Max algorithm to each vector-cluster to optimize the quantizer associated with the vector-cluster. Based on the optimization, the quantizer optimization unit 235 produces quantizer definitions for updating the quantizers 230. In an embodiment, the quantizers 230 are implemented as look-up tables, where each entry stores a quantization level. In an embodiment, the quantizer definitions comprise one or more of quantization levels, statistical proxy definitions, or quantizer configuration data, such as the quantized number format. Following optimization, the quantizer optimization unit 235 updates the quantizers 230 according to the quantizer definitions or to at least one of random values, calibrated statistical proxy definitions, or precomputed definitions. The vector to cluster mapping unit 225 and the quantizer optimization unit 235 may repeat the first and second steps to jointly optimize the vector-clustering and the per-cluster quantization until a criterion is satisfied (convergence to a local minimum, a fixed number of iterations (M), etc.). When the criterion is satisfied, the quantizers 230 output the quantized vectors.

FIG. 2B is a conceptual diagram illustrating a vector of parameters 210 associated with a quantizer 221 and metadata 205, suitable for use in implementing some embodiments of the present disclosure. Metadata 205 associated with each vector indicates the quantizer index [symbol] of the quantizer associated with the vector cluster to which the vector is mapped and the normalization factor mⱼ used to normalize the vector. As shown in FIG. 2B, the metadata 205 includes the quantizer index 212 identifying the quantizer 221.

In an embodiment, the quantizer 221 is implemented as a look-up table (LUT). The metadata 205 selects the quantizer 221 to which the vector of parameters 210 is mapped and each parameter of the vector is encoded as an index to the nearest quantization level in the quantizer 221. In other words, the parameters are replaced with indices for quantization levels to quantize the parameters. As shown in FIG. 2B, two of the parameters in the vector of parameters are replaced with entry index 215 and 217 corresponding to two different entries in the codebook or LUT-based quantizer 221. In an embodiment, each parameter in the vector of parameters 210 is replaced with the quantization level associated with the parameter. Although the quantizer 221 and quantizer 222 each include 8 entries, in other embodiments the quantizer 221 and 222 may be implemented with less than or more than 8 entries.

Given a set of quantizers 230 implemented as LUTs, {Tᵢ}ᵢ₌₁^{N}^{_{q}}, a normalized vector \tilde{ν}ⱼ is quantized by first evaluating f(\tilde{ν}ⱼ) to map to T_{f(\tilde{ν}}_{ⱼ}₎ and LUT-based quantization is performed as follows:

$${\hat{𝓋}}_{j} [ l ] = {arg min}_{k = 1 … {2}^{B}} {\vert {\hat{𝓋}}_{j} [ l ] - {T}_{f ( {\hat{𝓋}}_{j} )} [ k ] \vert}^{2}$$

where the notation a[b] is used to describe the b^{th} element in an arbitrary vector a. That is, each scalar in \hat{ν}ⱼ is an index to the closest entry in T_{f(\tilde{ν}}_{ⱼ}₎. Since T_{f(\tilde{ν}}_{ⱼ}₎ is a 2^{B}-entry LUT, the bitwidth of each scalar in \hat{ν}ⱼ is B-bits. Further, the metadata associated with each quantized vector \hat{ν}ⱼ is a set of two elements: the result of mapping function [symbol] ⱼ=f(\tilde{ν}ⱼ) and the quantized per-vector normalization factor \hat{m}ⱼ. In an embodiment, \hat{m}ⱼ is computed for a given mⱼ, m_{X} (absolute maximum value of νⱼ and X, respectively) and floating-point format m_{format} by invoking equations (1) and (2).

The quantized parameters may be obtained by de-referencing the indices in the vector of parameters 210. Given a quantized vector operand \hat{ν}ⱼ and the corresponding per-vector metadata { [symbol] ⱼ, mⱼ}, \hat{ν}ⱼ is de-referenced in a two-level hierarchical look-up operation. First, the quantizer LUT is selected using [symbol] ⱼ and then a scalar \hat{ν}ⱼ[l] in \hat{ν}ⱼ is de-referenced as [symbol] [\hat{ν}ⱼ[l]]. In an embodiment, when each entry is quantized to 8-bits in the quantizer LUTs, the bitwidth of each de-referenced value is 8-bits.

FIG. 2C illustrates graphs 240 and 245 of quantized vector clusters, in accordance with an embodiment. The vectors in each cluster are normalized and quantized using vector clustered quantization. Vectors with similar value distributions are clustered together and each cluster is optimally quantized. For instance, all the vectors in the vector-cluster in the quantized vector clusters 240 have no scalars in the range (−0.9, −0.4) and in the quantized vector clusters 245 have no values in ranges (0, 0.25) and (0.65, 0.75). No quantized representation is allocated to the empty regions. Further, a majority of the per-cluster quantizers cannot be mapped to any known number-format, necessitating an LUT-based quantizer implementation.

FIG. 2D illustrates a flowchart of a method 250 for vector clustered quantization, in accordance with an embodiment. Each block of method 250, described herein, comprises a computing process that may be performed using any combination of hardware, firmware, and/or software. For instance, various functions may be carried out by a processor executing instructions stored in memory. The method may also be embodied as computer-usable instructions stored on computer storage media. The method may be provided by a standalone application, a service or hosted service (standalone or in combination with another hosted service), or a plug-in to another product, to name a few. In addition, method 250 is described, by way of example, with respect to the vector clustered quantization system 200 of FIG. 2A. However, this method may additionally or alternatively be executed by any one system, or any combination of systems, including, but not limited to, those described herein. Furthermore, persons of ordinary skill in the art will understand that any system that performs method 250 is within the scope and spirit of embodiments of the present disclosure.

At step 255, a plurality of quantizers is initialized for a bitwidth. The quantizers 230 are initialized using initialization data. In an embodiment, the initialization data comprises at least one of quantizer definitions, random values, calibrated statistical proxy definitions, or precomputed definitions. In an embodiment, the quantizers are initialized to quantize each parameter to a bitwidth that is less than the bitwidth of the parameter before quantization. In an embodiment, the bitwidth is 4, 6, 8, or any other integer number of bits.

At step 260, vectors of parameters are mapped into clusters based on quantization errors, where each one of the clusters is associated with one quantizer of the plurality of quantizers. In an embodiment, the quantization errors are mean-squared errors. In an embodiment, the vectors of parameters are normalized before being mapped. In an embodiment, the normalize unit 220 computes the normalized vectors. In an embodiment, the vector to cluster mapping unit 225 performs step 260. In an embodiment, the parameters are at least one of weights or activations. In an embodiment, at least a portion of the parameters are activations that are dynamically calculated at each layer of a neural network model. In an embodiment, the parameters comprise vectors of elements within a single dimension of a multi-dimensional parameter tensor.

In an embodiment, mapping the vectors into clusters based on quantization errors comprises, for each vector: computing the quantization errors resulting from quantizing each parameter in the vector using each quantizer to produce per-vector quantizer errors; and mapping the vector to the cluster associated with the one quantizer of the plurality of quantizers for which a minimal per-vector quantizer error is produced.

In an embodiment, mapping the vectors into clusters based on quantization errors comprises, for each vector: determining a per-vector statistical proxy corresponding to quantization error, wherein each quantizer is associated with a quantizer statistical proxy definition; and mapping the vector to the cluster associated with the one quantizer of the plurality of quantizers producing a minimal difference between the per-vector statistical proxy and the quantizer statistical proxy definition. In an embodiment, the per-vector statistical proxy comprises at least one of a mean value of the parameters in the vector, an absolute mean value of the parameters in the vector, a median value of the parameters in the vector, an absolute median value of the parameters in the vector, or a maximum value and minimum value of the parameters in the vector. In an embodiment, initializing the plurality of quantizers comprises: for each vector, determining the per-vector statistical proxy; identifying a centroid for each cluster by applying K-means clustering to the per-vector statistical proxies; and, for each cluster, storing the centroid identified for the cluster as the quantizer statistical proxy definition for the quantizer associated with the cluster. In an embodiment, initializing the plurality of quantizers further comprises: optimizing at least a portion of the quantizers in the plurality based on computed initial per-cluster quantization errors to produce optimized quantizers; and for each cluster, storing a quantizer definition for the optimized quantizer associated with the cluster.

At step 265, at least a portion of the quantizers in the plurality of quantizers is optimized based on computed per-cluster quantization errors to produce optimized quantizers. In an embodiment, the quantizer optimization unit 230 performs step 265. In an embodiment, a Lloyd-Max algorithm is used to optimize each quantizer in the portion of the quantizers. In an embodiment, steps 260 and 265 are repeated to jointly optimize the vector-clustering and the per-cluster quantization until a criterion is satisfied (convergence to a local minimum, a fixed number of iterations, etc.). In an embodiment, before the steps 260 and 265 are repeated, at least one quantizer in the plurality with one of the optimized quantizers is replaced with a different quantizer to update the optimized quantizers. For example, the at least one quantizer may be replaced with an updated quantizer that was optimized at step 265 or the one quantizer may be re-initialized using the initialization data.

At step 270, the parameters of the vectors in each cluster are quantized using the optimized quantizer for the cluster to produce quantized vectors comprising quantized parameters at the bitwidth. At step 275, the quantized vectors are processed by performing operations at the bitwidth by a layer of a neural network model to produce output values.

The inference accuracy of LLMs during per-vector (fine-grained) quantization is significantly influenced by the number format of the vectors and per-vector scale factors. Vector clustered quantization is an optimal vector clustering and quantization algorithm that achieves a local minima of quantization MSE. Vector clustered quantization achieves <1% perplexity loss across a suite of LLMs. Further, the computation workload may be reduced by replacing a number of the codebook quantizers with fixed number format quantizers and/or clustering based on statistical proxies rather than minimal MSE. Even when the computational workload is reduced, the perplexity degradation is maintained <2% compared to an unquantized baseline.

For a given neural network model, calibration may be performed by applying vector cluster quantization on a set of vectors that includes a randomly selected batch of inputs and weights to generate quantizer definitions. In an embodiment, vectorwise-decomposition is performed on a tensor X, to produce calibration vectors of length L_{ν}, the vectors are normalized and then mapped to a number of clusters N_{q}. A set of quantizers [symbol] associated with the clusters may be randomly initialized. The set of quantizers are optimized for each cluster and [symbol] is stored as a set of codebooks, LUTs {Tᵢ}ᵢ₌₁^{N}^{_{q}}, each LUT having 2^{B} quantization levels for the entries. The set of LUTs comprise quantizer definitions.

As previously described, the quantized vectors of parameters may be processed by one or more layers of a neural network model. While weight parameters are readily available before the neural network model is deployed for inference, the activation parameters are dynamically generated by each layer during inference. Performing vector-clustering by quantizing each vector using each one of the quantizers to identify each vector to the quantizer that minimizes the quantization error for the vector, performing N_{q} quantization operations, is computationally expensive and resource-intensive for large N_{q}. In an embodiment, calibration may be performed before inference to compute statistical proxies that approximate the MSE results for clustering. The calibration defines quantizer statistical proxy definitions for vector clustering as well as quantizer definitions (quantization levels stored in the codebooks). Instead of MSE-based clustering during inference, heuristical clustering may be performed based on simple vector-level statistics, e.g., per-vector statistical proxies.

Referring back to FIG. 2A, in an embodiment, the vector to cluster mapping unit 225 maps the vectors to N_{q} clusters based on quantization errors. Instead of using the computationally expensive per-vector computed MSEs for each of the quantizers for vector clustering, statistical proxies are determined that correspond to the quantization errors. In an embodiment, the statistical proxies are output as quantizer statistical proxy definitions. The quantization levels computed during optimization of the quantizers 230 by the quantizer optimization unit 235 are output as quantizer definitions.

In an embodiment, mapping the vectors into clusters based on quantization errors at step 265 of the method 250 comprises, for each vector: computing the quantization errors resulting from quantizing each parameter in the vector using each quantizer to produce per-vector quantizer errors; and mapping the vector to the cluster associated with the one quantizer of the plurality of quantizers for which a minimal per-vector quantizer error is produced.

In an embodiment, mapping the vectors into clusters based on quantization errors at step 265 comprises, for each vector: determining a per-vector statistical proxy corresponding to quantization error, wherein each quantizer is associated with a quantizer statistical proxy definition; and mapping the vector to the cluster associated with the one quantizer of the plurality of quantizers producing a minimal difference between the per-vector statistical proxy and the quantizer statistical proxy definition. In an embodiment, the per-vector statistical proxy comprises at least one of a mean value of the parameters in the vector, an absolute mean value of the parameters in the vector, a median value of the parameters in the vector, an absolute median value of the parameters in the vector, or a maximum value and minimum value of the parameters in the vector. In an embodiment, initializing the plurality of quantizers at step 255 comprises: for each vector, determining the per-vector statistical proxy; identifying a centroid for each cluster by applying K-means clustering to the per-vector statistical proxies; and, for each cluster, storing the centroid identified for the cluster as the quantizer statistical proxy definition for the quantizer associated with the cluster. In an embodiment, initializing the plurality of quantizers further comprises: optimizing at least a portion of the quantizers in the plurality based on computed initial per-cluster quantization errors to produce optimized quantizers; and for each cluster, storing a quantizer definition for the optimized quantizer associated with the cluster.

The lookup operations performed during optimization of the quantizers implemented as codebooks during step 265 can be computationally expensive for large number of vector clusters. Therefore, in an embodiment, at least one quantizer in the quantizers 230 is replaced with a set of 4-bit number formats that achieve comparable quantization MSE. In an embodiment, the quantizers 230 comprises a combination of fixed number format quantizers and codebook quantizers. Unlike the codebook quantizers, the fixed number format quantizers are not optimized during step 265 and remain unchanged during step 265.

Typically, any FP (floating-point) format, denoted as EₓM_{y} where Eₓ is the number of exponent bits and M_{y} is the number of mantissa bits, and the remaining bit is the sign. The FP formats may be associated with a constant bias that is applied to the exponent. For instance, an exponent bias of 1 is associated with the E2M1 format. In a bFP format, the bias is applied to all the exponents except the maximum exponent. In an embodiment, the exponent bias is 2. In an embodiment, a biased unsigned 4-bit integer format (BUINT4) is implemented, where each vector is first shifted by a bias to convert the vector to a range of [0,max] and then normalized to a range [0,1] before quantization to an unsigned 4-bit integer format (UINT4) In an embodiment, the bias and normalization factor are quantized to low precision. In an embodiment, an asymmetric 4-bit integer format (asymmINT4) is implemented that has quantization levels equally distributed between given maximum and minimum values. In an embodiment, randomly generated (max,min) pairs in the range [−1,1] are used to derive fixed number format quantizers for asymmINT4.

In an embodiment, the fixed number format quantizers implement one or more of FP4(E2M1), FP4(E1M2), INT4, or a bias-adjusted format (e.g., bE2M1 or bUINT4 with a bias of 1 or 2). In an embodiment, bUINT4 quantization achieves both computationally efficient vector-clustering and per-cluster quantization while minimizing the accuracy degradation to <2%.

### Energy-Efficient Datapath for Vector-Scaled Hierarchical Codebook Quantization

A datapath for vector-scaled hierarchical codebook quantization reduces precision (bitwidth) of vectors and may enable energy-efficient acceleration of deep neural networks. The memory footprint of a neural network model is reduced when the parameters (e.g., weights and/or activations) for the trained model are quantized and stored in a quantized representation. A vector (block array) comprises one or more parameters (elements, scalars, or values) within a single dimension of a multi-dimensional tensor (or kernel) that is input to dot product computations. For example, in an embodiment, a block array comprises 4 sub-vectors (blocks) and each sub-vector comprises 8 parameters. The parameters may be represented in integer, floating-point, or any other suitable format.

The block array cluster quantization technique may be used to quantize the weights because the weights are known in advance, so the two-phase block-clustering alternating with cluster optimization algorithm can be performed to encode the weights and determine values stored in each codebook. In an embodiment, because the activations are dynamically computed during inference and not known in advance, a calibration dataset that is representative of the dynamically generated activations may be used to determine values stored in each codebook for the representative activations. Therefore, in an embodiment, fixed codebooks determined by calibration are used to quantize the weights and activations in real-time during inference. Hardware circuitry within the datapath identifies an optimal codebook of a plurality of codebooks for quantizing each block of parameters and the block is encoded using the identified codebook. During processing, the identified codebook is used to obtain the quantized parameter and perform computations at the reduced precision. The hardware circuitry may be used to encode quantized parameters for weights and/or activations in real time. For vector-scaled quantization, the parameters are first normalized using a per-block array scale factor. The normalized elements are then quantized.

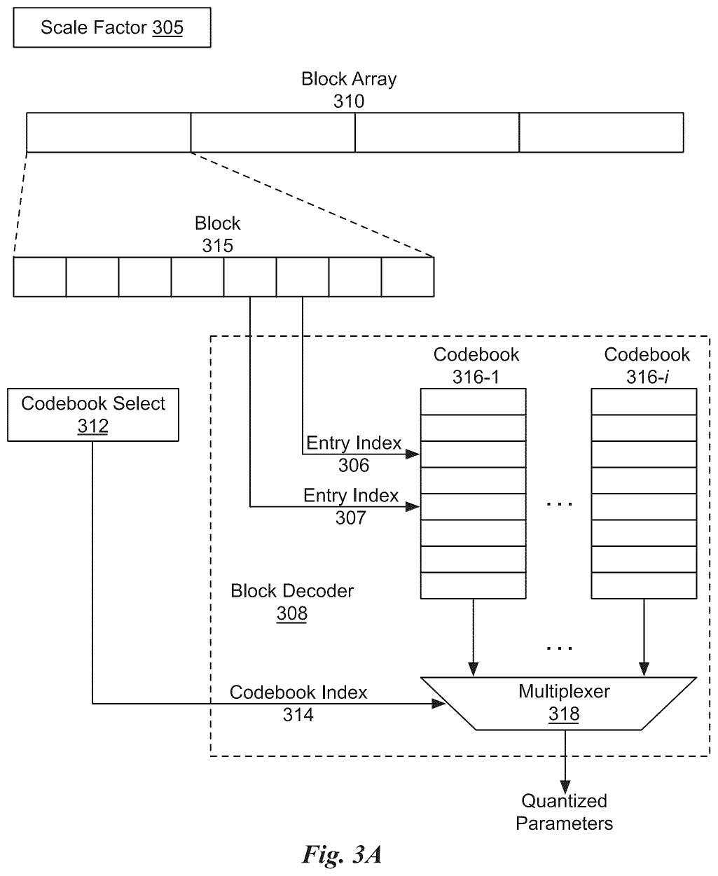

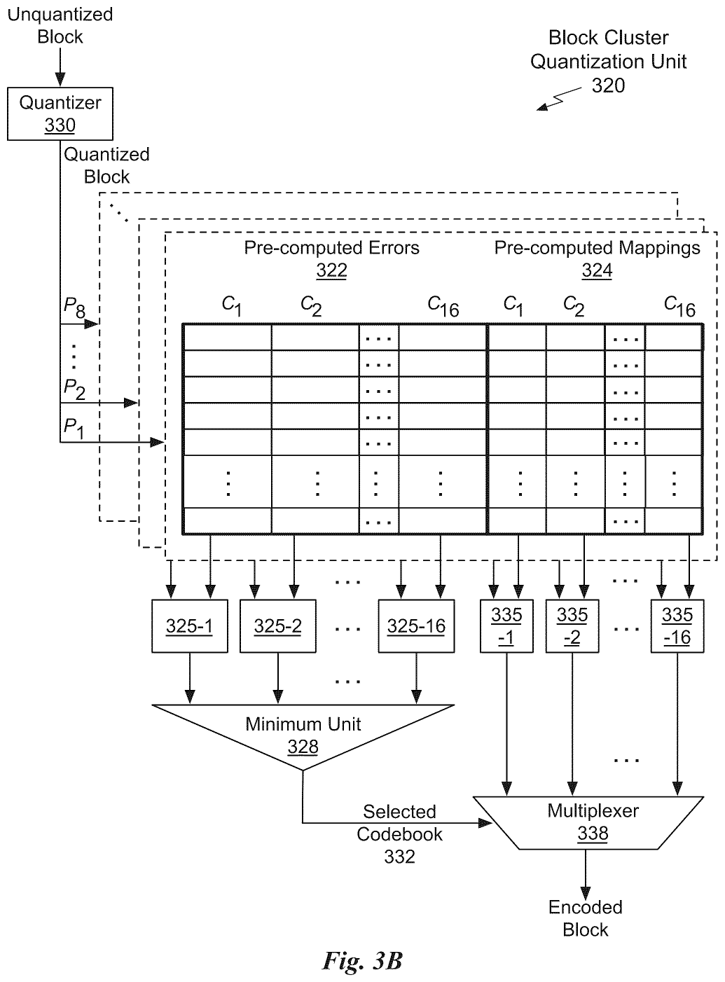

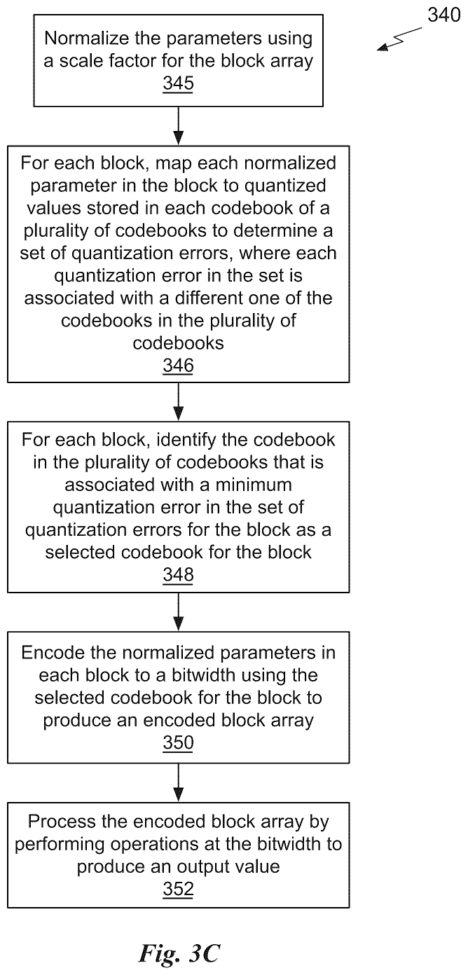

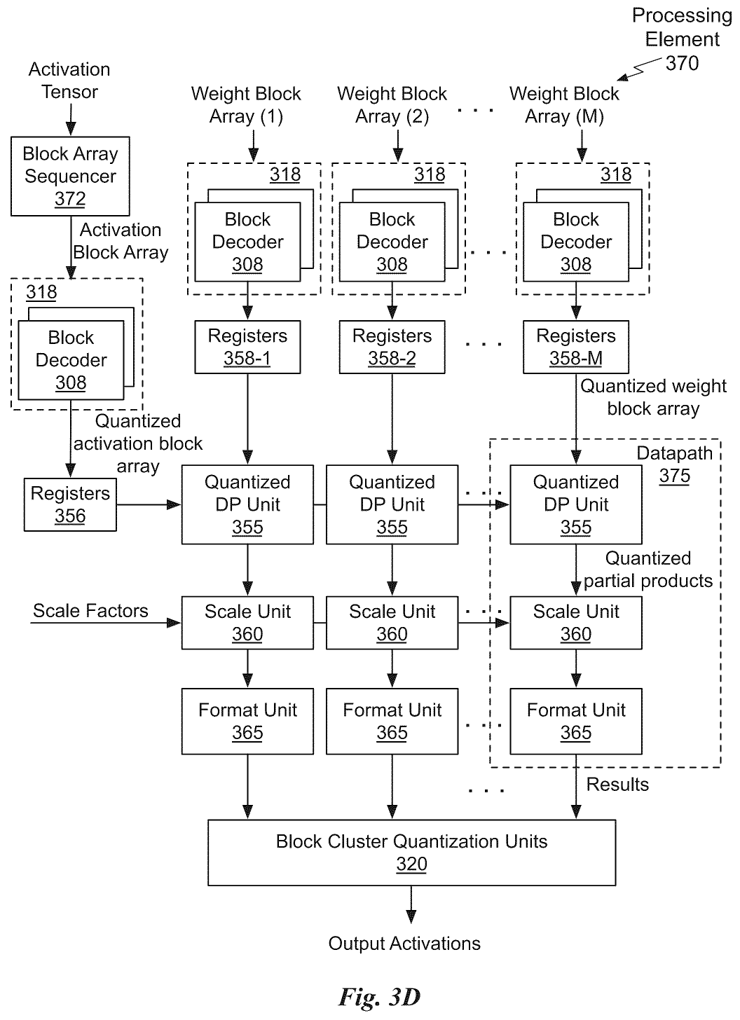

FIG. 3A is a conceptual diagram illustrating a block array 310 of four blocks 315 that are each associated with a codebook and indices, suitable for use in implementing some embodiments of the present disclosure. The block array 310 may represent a quantized vector that is associated with a scale factor 305 and comprises four blocks 315 (sub-vectors). Each block 315 is associated with a codebook select 312 that identifies (selects) one codebook (quantizer LUT) in a set of codebooks including at least codebooks 316-1 through 316-i. The quantized parameters of the block 315 are encoded as indices (e.g., entry indices 306 and 307) to the entries in the one codebook. A block decoder 308 receives the codebook select 312 and entry indices corresponding to each parameter encoded in the block 315 and outputs the quantized parameters for the block 315. The codebook index 314 selects the quantized parameters that are obtained by reading entries referenced by the entry indices for the selected codebook 316.

In an embodiment, each codebook 316 in the set of codebooks may each be associated with a different block 315 in the block array 310. In an embodiment, at least one codebook 316 is associated with two or more blocks 315 in the block array 310. In an embodiment, each codebook includes sixteen entries and each entry index is a four bit index. In an embodiment, each entry stores a 6-bit value in one of the formats INT6, E2M3, and E3M2. For example, the codebooks 316-1 and 316-2 may each store sixteen 6-bit signed integer values (−31, −26, −22, −17, −13, −9, −6, −3, 0, 2, 5, 9, 13, 17, 23, 31) and (−20, −15, −11, −8, −6, −3, −1, 1, 4, 7, 11, 15, 18, 21, 26, 31), respectively. Each parameter is encoded as a 4-bit index that is used to obtain a 6-bit value from the codebook. Each codebook may store values having asymmetric and/or non-uniform distributions or uniform distributions.

In an embodiment, at least one codebook is implemented using a read-only memory circuit (ROM). In an embodiment, contents of the codebooks implemented as ROM are optimized across datasets from different neural network models and are fixed values. Implementing the codebooks as ROMs achieves high efficiency for both die area and energy while maintaining accuracy for many neural network models. In an embodiment, at least one codebook is implemented using a programmable read-write memory circuit. In contrast with codebooks implemented as ROM, the codebooks implemented as programmable read-write memory may be changed at runtime. Implementing the codebooks as programmable read-write memory is energy efficient. In an embodiment, the read-write memory circuit is implemented as latch array, flip-flop array, static random access memory (SRAM), and the like. In an embodiment, custom codebooks may be calibrated and programmed at a neural network model and/or layer level granularity. In an embodiment, a smaller number of codebooks are implemented as programmable read-write memories compared with ROMs. In an embodiment the codebooks implemented as programmable read-write memories are loaded from memory once and reused to perform computations.

In an embodiment, each element of the block 315 is encoded as a four-bit index to the closest representation in the codebook 316. In an embodiment, the codebooks are calibrated to minimize the quantization mean-squared error (MSE) on typical value distributions of LLM operands. By allowing each operand block 315 to map to the codebook that minimizes quantization MSE, post-training quantization (PTQ) accuracy is improved compared with conventional quantization techniques that map all operand blocks to a fixed number format. Accuracy increases as the number of bits in each entry increases and/or as the number of entries increases. However, energy efficiency and processing performance increases as the number of bits in each entry decreases.

In an embodiment, the parameters are quantized using block cluster quantization (previously described as vector-clustered quantization). The block cluster quantization technique may be used to quantize the weights of a pre-trained neural network model because the weights are known in advance, so the two-phase block-clustering alternating with cluster optimization algorithm can be performed to encode the weights and optimize values stored in each codebook. However, a less elaborate technique is needed to quantize activations (or weights) in real-time using hardware circuitry implemented.

FIG. 3B illustrates a block diagram of an example block cluster quantization unit 320 suitable for use in implementing some embodiments of the present disclosure. The example block cluster quantization unit 320 includes the quantizer 330, pre-computed errors 322, pre-computed mappings 324, adder trees 325, a minimum unit 328, encoded block units 335, and a multiplexer 338. It should be understood that this and other arrangements described herein are set forth only as examples. Other arrangements and elements (e.g., machines, interfaces, functions, orders, groupings of functions, etc.) may be used in addition to or instead of those shown, and some elements may be omitted altogether. Further, many of the elements described herein are functional entities that may be implemented as discrete or distributed components or in conjunction with other components, and in any suitable combination and location. Various functions described herein as being performed by entities may be carried out by hardware, firmware, and/or software. For instance, various functions may be carried out by a processor executing instructions stored in memory. Furthermore, persons of ordinary skill in the art will understand that any system that performs the operations of the block cluster quantization unit 320 is within the scope and spirit of embodiments of the present disclosure.

The quantizer 330 receives an unquantized block of parameters. In an embodiment, the unquantized parameters have been normalized using a scale factor that is shared by all parameters in the block array. The normalized parameters are then quantized to the same bitwidth and number format as the codebook entries to produce a quantized block including the quantized parameters. The quantized normalized parameters for the block are then mapped to one of the codebooks Cᵢ. In an embodiment, the number of entries in the codebooks is 16, so that 4-bit indices are used to encode 6-bit quantized normalized parameters. In an embodiment, an effective bit-width of a parameter is

$$4 + \frac{B {W}_{idx}}{{L}_{b}} + \frac{B {W}_{scale}}{{L}_{A}} ,$$

where L_{b} is the block size (number of quantized normalized parameters), L_{A} is the block array size, BW_{idx} is the bitwidth of the codebook indices, and BW_{scale} is the bitwidth of the scale factor.

In an embodiment, all of the codebooks Cᵢ are associated with the pre-computed errors 322 and pre-computed mappings 324. In an embodiment, the pre-computed errors 322 and pre-computed mappings 324 are stored in a look-up table. To process all quantized normalized parameters in the quantized block in parallel, a dedicated pre-computed errors 322 and pre-computed mappings 324 is used for each one of the quantized normalized parameters. As shown in FIG. 3B, the number of quantized normalized parameters (Pₙ) in the quantized block is n=8.

Each 6-bit integer quantized normalized parameter Pₙ is mapped to a closest value of a fixed quantity of possible quantized values in each one of the codebooks Cᵢ. In an embodiment, each codebook entry stores an INT6 number corresponding to a quantized value and a total number of entries in each codebook is sixteen and the number of codebooks i=16. The quantization errors for all possible quantized values in each codebook can be pre-computed and stored as the pre-computed errors 322 (ROM or read-write memory).

Assuming a block size of n=8, eight pre-computed errors are output for each codebook. Each adder tree 325 sums the pre-computed errors for the block when one of the codebooks is used. For example, the adder tree 325-1 sums the pre-computed errors for each quantized normalized parameter using the codebook C₁ to compute the per-block error for the codebook C₁. The one codebook providing the minimum per-block error is identified by the minimum unit 328 and the codebook index of the one codebook is output as a selected codebook 332 for the block.

The block of quantized normalized parameters is simultaneously encoded for (mapped to) each of the codebooks Cᵢ. The encoded block units 335 each output per-quantized normalized parameter indices for the block using each codebook. For example, the encoded block unit 335-1 encodes the quantized normalized parameters using the codebook C₁, providing an entry index for each of the 8 quantized normalized parameters in the block. The multiplexer 338 selects the entry indices using the selected codebook 332 to produce the encoded block. In an embodiment, a dedicated block cluster quantization unit 320 is instantiated for each block 315 in a block array 310 to encode the blocks 315 for the entire block array 310 in parallel. In an embodiment, multiple block cluster quantization units 320 are implemented to process multiple blocks in a block array in parallel for higher performance.

FIG. 3C illustrates a flowchart of a method 340 for processing parameters, in accordance with an embodiment. Each block of method 340, described herein, comprises a computing process that may be performed using any combination of hardware, firmware, and/or software. For instance, various functions may be carried out by a processor executing instructions stored in memory. The method may also be embodied as computer-usable instructions stored on computer storage media. The method may be provided by a standalone application, a service or hosted service (standalone or in combination with another hosted service), or a plug-in to another product, to name a few. In addition, method 340 is described, by way of example, with respect to the block cluster quantization unit 320 of FIG. 3B. However, this method may additionally or alternatively be executed by any one system, or any combination of systems, including, but not limited to, those described herein. Furthermore, persons of ordinary skill in the art will understand that any system that performs method 340 is within the scope and spirit of embodiments of the present disclosure.

A block array including parameters organized into blocks is stored in a memory, where each block includes a subset of the parameters. At step 345, the parameters are normalized using a scale factor for the block array. More specifically, in an embodiment, a single scale factor is used to normalize all parameters in the block array.

At step 346, for each block, each (quantized) normalized parameter in the block is mapped to quantized values stored in each codebook of a plurality of codebooks to determine a set of quantization errors. Each quantization error in the set of quantization errors is associated with a different one of the codebooks in the plurality of codebooks. In an embodiment, the set of quantization errors are output by the adder trees 325. In an embodiment, each quantization error in the set of quantization errors for each block is computed as one of a sum of pre-computed errors of the quantized values stored in a different one of the codebooks in the plurality of codebooks mapped to the normalized parameters in the block. In an embodiment, each quantization error in the set of quantization errors for each block is computed as one of a sum of pre-computed squared errors of the quantized values stored in a different one of the codebooks in the plurality of codebooks mapped to the normalized parameters in the block. In an embodiment, the quantization errors in the set of quantization errors for each block are determined using a look-up table that stores an error for each possible value of the normalized parameters stored in the plurality of codebooks. In an embodiment, wherein the sets of quantization errors for the blocks are determined in parallel.

In an embodiment, at least one of the codebooks in the plurality stores values in a fixed number format including one of E2M1, E1M2, INT4, UINT4, INT6, UINT6, or a bias-adjusted format. In an embodiment, at least one codebook in the plurality of codebooks is implemented as a read-only-memory. In an embodiment, at least one codebook in the plurality of codebooks is implemented as a read-write memory.

At step 348, for each block, the codebook in the plurality of codebooks is identified that is associated with a minimum quantization error in the set of quantization errors for the block as a selected codebook for the block. In an embodiment, the minimum unit 328 identifies the selected codebook 332. In an embodiment, the selected codebooks for the blocks are identified in parallel.

At step 350, the normalized parameters in each block are encoded to a bitwidth using the selected codebook for the block to produce an encoded block array. In an embodiment, the bitwidth equals a bitwidth of indices corresponding to entries of the selected codebook that stores quantized versions of the subset of parameters in the encoded version. In an embodiment, the encoded block array comprises the scale factor and encoded versions of each block, where each encoded version includes an identifier for the selected codebook for the block and indices corresponding to entries of the selected codebook where quantized versions of the subset of parameters in the encoded version are stored. In an embodiment, the normalized parameters in each block are encoded by encoding the normalized parameters in the block using each of the codebooks to produce sets of codebook encoded parameters for the block; and selecting one set of the codebook encoded parameters corresponding to the selected codebook for the block as the encoded parameters included in the encoded block array.

At step 352, the encoded block array is processed by performing operations at the bitwidth to produce an output value. In an embodiment, the parameters are at least one of weights or activations. In an embodiment, the parameters are activations that are dynamically calculated at each layer of a neural network model. In an embodiment, the parameters comprise vectors of elements within a single dimension of a multi-dimensional parameter tensor.

In an embodiment, at least one of steps 345, 346, 348, 350, and 352 is performed on a server or in a data center and the encoded block array is streamed to a user device. In an embodiment, at least one of steps 345, 346, 348, 350, and 352 is performed within a cloud computing environment. In an embodiment, at least one of steps 345, 346, 348, 350, and 352 is performed for training, testing, or certifying a neural network model employed in a machine, robot, or autonomous vehicle. In an embodiment, at least one of steps 345, 346, 348, 350, and 352 is performed on a virtual machine comprising a portion of a graphics processing unit. In an embodiment, at least one of steps 345, 346, 348, 350, and 352 is implemented to include advanced error correction, fault-tolerance, and self-healing capabilities.

FIG. 3D illustrates a block diagram of a processing element 370 suitable for use in implementing some embodiments of the present disclosure. The processing element 370 comprises a block sequencer 372, block decoders 308, registers 356 and 358, datapaths 375, and block cluster quantization units 320. Each datapath 375 includes a quantized dot-product (DP) unit 355, scale unit 360, and format unit 365. Various functions described herein as being performed by entities may be carried out by hardware, firmware, and/or software. For instance, various functions may be carried out by a processor executing instructions stored in memory. Furthermore, persons of ordinary skill in the art will understand that any system that performs the operations of the processing clement 370 is within the scope and spirit of embodiments of the present disclosure.

The processing element 370 computes M dot product operations. Each dot-product is computed between two block arrays (a weight block array and an activation block array), where M is the number of block arrays processed in parallel. Codebooks 216 in the block decoders 308 store the quantized weights and/or activations that are read using the entry indices in each respective encoded block. In an embodiment, the parameters for each block are converted from indices into integer values by retrieving the integer values from one of the codebooks 216 using the selected codebook for the block and the index for the quantized normalized parameter (activation or weight). In an embodiment, the indices are 4 bits and the integer values are 6 bits.

In an embodiment, multiple block decoders 308 are included in a block array decoder 318 to process multiple blocks in a weight block array or an activation block array in parallel. In an embodiment, the block array decoder 318 processes all of the blocks in a block array in parallel. In an embodiment, each block decoder 308 processes a block of parameters and each quantized DP unit 355 processes a block array to compute a dot-product. Each of the registers 358 stores a quantized weight block array and the registers 356 store the quantized activation block array. As shown in FIG. 3D, multiple block array decoders 318 operate in parallel to generate M quantized weight block arrays. In another embodiment (not shown), the registers 358 are double-buffered and a single block array decoder 318 generates a quantized weight block array each cycle, to generate M quantized weight block arrays over M cycles. After all M quantized weight block arrays are stored into a back buffer in the registers 358, the back buffer may be transferred (or swapped) with a front buffer in the registers 358 to output the new quantized weight blocks for processing by the quantized DP units 355. The double buffering can be implemented as ping-pong buffer by alternating read between front and back buffers without explicit transfer. Using a single block array decoder 318 instead of M block array decoders 318 to generate M quantized weight blocks reduces the circuitry footprint. Depending on area and performance constraints, one or more block array decoders 318 can be included in the processing element 370. One block decoder 308 can be used to generate a single quantized weight block per cycle and M quantized block arrays are generated in M*BA (Number of blocks in array block array) cycles. Further, in an embodiment, the block decoder 308 is designed to compute one element of the block per cycle and different elements of the block array can be computed across multiple cycles.

In an embodiment, a different block array of quantized weights from a weight block array is input to each quantized DP unit 355 and a single block array of quantized activations is input to all of the quantized DP units 355 each cycle until the entire activation tensor is processed. In an embodiment, as shown in FIG. 3D, the quantized parameters for weights are temporally reused and the quantized parameters for activations are spatially reused. More specifically, each processing cycle a different activation block array of the activation tensor is input to the “row” of the quantized DP units 355 while different weight block arrays are held at all of the quantized DP units 355 in the “columns”. The block sequencer 372 sequences through each activation block array in the activation tensor. In another embodiment, the quantized parameters for weights are spatially reused and the quantized parameters for activations are temporally reused.

Each quantized DP datapath unit 355 may compute sums of weight-activation products over multiple cycles where each cycle uses a different quantized activation block array. Each activation block array is processed in one cycle to output a partial sum. The partial sums are accumulated over multiple cycles to produce a dot product of multiple activation block arrays and weight block arrays. The weight block arrays are reused across multiple cycles to compute partial sums with different input activation block arrays to produce different partial sums. For each quantized DP unit 355, all of the quantized activations share a first scale factor and all of the quantized weights share a second scale factor, so that each scale unit 360 multiplies the quantized partial product output by the quantized DP 355 by the first and second scale factors.

The format units 365 receive scaled values (quantized partial products) from the scale units 360 and perform alignment operations before accumulating aligned scaled values and then normalizing the accumulated values to each produce a result, an element of the multi-dimensional output tensor. The aligned scaled values may be temporally accumulated across multiple cycles in the format units 365 before being normalized to produce the results. The results may then be output by the processing element 370 or quantized for input to another processing unit 370 or another layer of the neural network. As shown in FIG. 3D, the results are input to a block cluster quantization units 320 for encoding into a quantized format.

When the output activations for a neural network layer have been computed and quantized by the block cluster quantization units 320, the neural network may proceed to process a next layer by applying the output activations as input activations. Additional block cluster quantization units 320 may also be used to quantize the activations and the weights for input to the first layer of a neural network.

In an embodiment, weight-activation products are computed and summed to produce vector dot products that are accumulated to compute elements of a multi-dimensional output tensor. The elements of the output tensor are input activations to a subsequent layer of the neural network. Quantizing the elements of the output tensor (activations) reduces the memory footprint needed to store the output tensor and reduces the bandwidth consumed to transmit the output tensor. Similarly, quantizing weights reduces the memory footprint needed to store the weights, reduces the bandwidth consumed to transmit the weights, and reduces the number of bits used for the dot product computations.

The hierarchical codebook representation allows each block of parameters to map to one out of a set of available codebooks 316, resulting in improved accuracy compared with using a single codebook 316. The codebooks 316 may be calibrated to minimize the quantization MSE on typical value distributions of LLM operands and fix (freeze) the codebooks 316 during inference, enabling ROM-based codebooks 316. The energy-efficient datapaths 375 reference the codebooks on-the-fly and perform multiply-accumulate operations at reduced bitwidths using quantized values.

### Parallel Processing Architecture

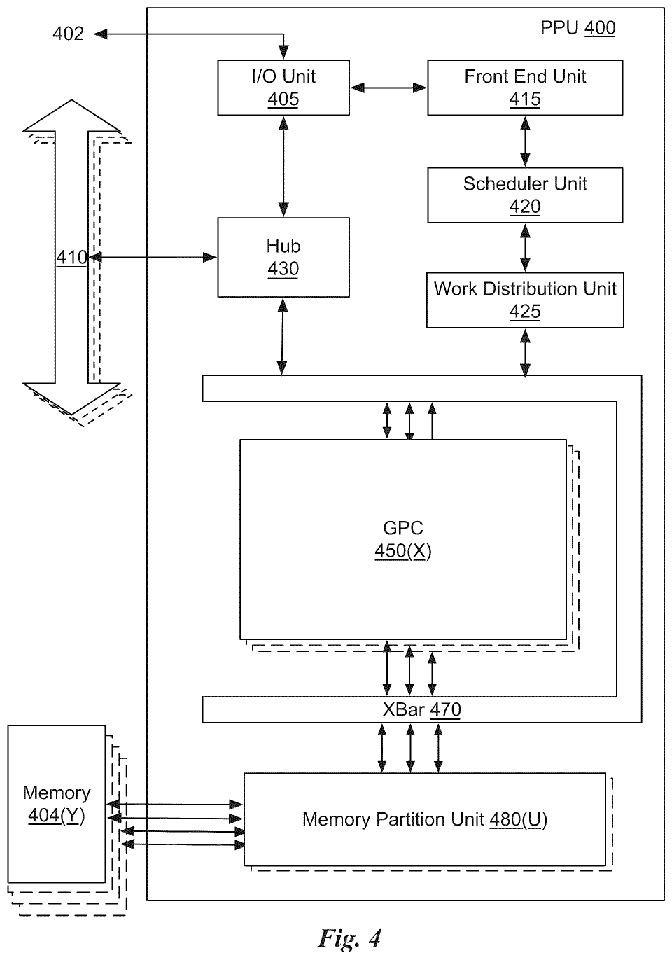

FIG. 4 illustrates a parallel processing unit (PPU) 400, in accordance with an embodiment. The PPU 400 may be used to implement the vector clustered quantization system 200, the block cluster quantization unit 320, and/or the processing element 370. In an embodiment, a processor such as the PPU 400 may be configured to implement a neural network model. The neural network model may be implemented as software instructions executed by the processor or, in other embodiments, the processor can include a matrix of hardware elements configured to process a set of inputs (e.g., electrical signals representing values) to generate a set of outputs, which can represent activations of the neural network model. In yet other embodiments, the neural network model can be implemented as a combination of software instructions and processing performed by a matrix of hardware elements. Implementing the neural network model can include determining a set of parameters for the neural network model through, e.g., supervised or unsupervised training of the neural network model as well as, or in the alternative, performing inference using the set of parameters to process novel sets of inputs.

In an embodiment, the PPU 400 is a multi-threaded processor that is implemented on one or more integrated circuit devices. The PPU 400 is a latency hiding architecture designed to process many threads in parallel. A thread (e.g., a thread of execution) is an instantiation of a set of instructions configured to be executed by the PPU 400. In an embodiment, the PPU 400 is a graphics processing unit (GPU) configured to implement a graphics rendering pipeline for processing three-dimensional (3D) graphics data in order to generate two-dimensional (2D) image data for display on a display device. In other embodiments, the PPU 400 may be utilized for performing general-purpose computations. While one exemplary parallel processor is provided herein for illustrative purposes, it should be strongly noted that such processor is set forth for illustrative purposes only, and that any processor may be employed to supplement and/or substitute for the same.

One or more PPUs 400 may be configured to accelerate thousands of High Performance Computing (HPC), data center, cloud computing, and machine learning applications. The PPU 400 may be configured to accelerate numerous deep learning systems and applications for autonomous vehicles, simulation, computational graphics such as ray or path tracing, deep learning, high-accuracy speech, image, and text recognition systems, intelligent video analytics, molecular simulations, drug discovery, disease diagnosis, weather forecasting, big data analytics, astronomy, molecular dynamics simulation, financial modeling, robotics, factory automation, real-time language translation, online search optimizations, and personalized user recommendations, and the like.

As shown in FIG. 4, the PPU 400 includes an Input/Output (I/O) unit 405, a front end unit 415, a scheduler unit 420, a work distribution unit 425, a hub 430, a crossbar (Xbar) 470, one or more general processing clusters (GPCs) 450, and one or more memory partition units 480. The PPU 400 may be connected to a host processor or other PPUs 400 via one or more high-speed NVLink 410 interconnect. The PPU 400 may be connected to a host processor or other peripheral devices via an interconnect 402. The PPU 400 may also be connected to a local memory 404 comprising a number of memory devices. In an embodiment, the local memory may comprise a number of dynamic random access memory (DRAM) devices. The DRAM devices may be configured as a high-bandwidth memory (HBM) subsystem, with multiple DRAM dies stacked within each device.

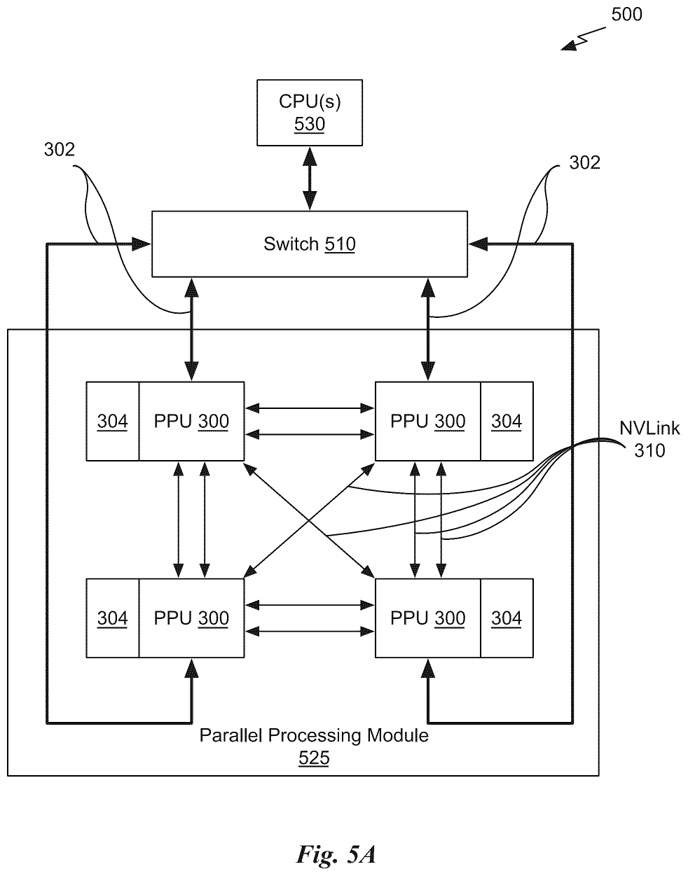

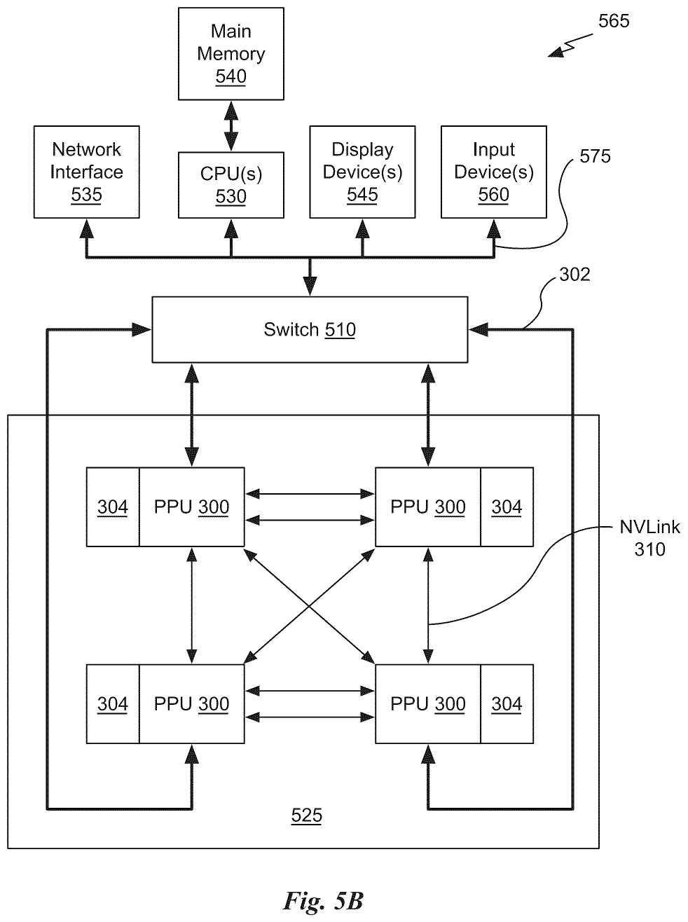

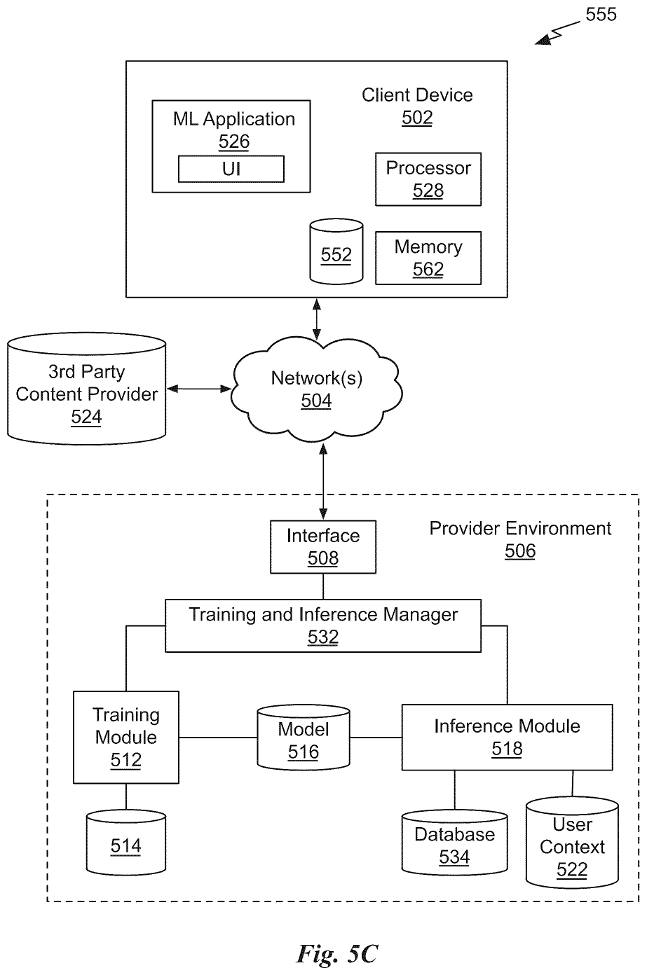

The NVLink 410 interconnect enables systems to scale and include one or more PPUs 400 combined with one or more CPUs, supports cache coherence between the PPUs 400 and CPUs, and CPU mastering. Data and/or commands may be transmitted by the NVLink 410 through the hub 430 to/from other units of the PPU 400 such as one or more copy engines, a video encoder, a video decoder, a power management unit, etc. (not explicitly shown). The NVLink 410 is described in more detail in conjunction with FIG. 5B.

The I/O unit 405 is configured to transmit and receive communications (e.g., commands, data, etc.) from a host processor (not shown) over the interconnect 402. The I/O unit 405 may communicate with the host processor directly via the interconnect 402 or through one or more intermediate devices such as a memory bridge. In an embodiment, the I/O unit 405 may communicate with one or more other processors, such as one or more the PPUs 400 via the interconnect 402. In an embodiment, the I/O unit 405 implements a Peripheral Component Interconnect Express (PCIe) interface for communications over a PCIe bus and the interconnect 402 is a PCIe bus. In alternative embodiments, the I/O unit 405 may implement other types of well-known interfaces for communicating with external devices.

The I/O unit 405 decodes packets received via the interconnect 402. In an embodiment, the packets represent commands configured to cause the PPU 400 to perform various operations. The I/O unit 405 transmits the decoded commands to various other units of the PPU 400 as the commands may specify. For example, some commands may be transmitted to the front end unit 415. Other commands may be transmitted to the hub 430 or other units of the PPU 400 such as one or more copy engines, a video encoder, a video decoder, a power management unit, etc. (not explicitly shown). In other words, the I/O unit 405 is configured to route communications between and among the various logical units of the PPU 400.

In an embodiment, a program executed by the host processor encodes a command stream in a buffer that provides workloads to the PPU 400 for processing. A workload may comprise several instructions and data to be processed by those instructions. The buffer is a region in a memory that is accessible (e.g., read/write) by both the host processor and the PPU 400. For example, the I/O unit 405 may be configured to access the buffer in a system memory connected to the interconnect 402 via memory requests transmitted over the interconnect 402. In an embodiment, the host processor writes the command stream to the buffer and then transmits a pointer to the start of the command stream to the PPU 400. The front end unit 415 receives pointers to one or more command streams. The front end unit 415 manages the one or more streams, reading commands from the streams and forwarding commands to the various units of the PPU 400.

The front end unit 415 is coupled to a scheduler unit 420 that configures the various GPCs 450 to process tasks defined by the one or more streams. The scheduler unit 420 is configured to track state information related to the various tasks managed by the scheduler unit 420. The state may indicate which GPC 450 a task is assigned to, whether the task is active or inactive, a priority level associated with the task, and so forth. The scheduler unit 420 manages the execution of a plurality of tasks on the one or more GPCs 450.

The scheduler unit 420 is coupled to a work distribution unit 425 that is configured to dispatch tasks for execution on the GPCs 450. The work distribution unit 425 may track a number of scheduled tasks received from the scheduler unit 420. In an embodiment, the work distribution unit 425 manages a pending task pool and an active task pool for each of the GPCs 450. As a GPC 450 finishes the execution of a task, that task is evicted from the active task pool for the GPC 450 and one of the other tasks from the pending task pool is selected and scheduled for execution on the GPC 450. If an active task has been idle on the GPC 450, such as while waiting for a data dependency to be resolved, then the active task may be evicted from the GPC 450 and returned to the pending task pool while another task in the pending task pool is selected and scheduled for execution on the GPC 450.

In an embodiment, a host processor executes a driver kernel that implements an application programming interface (API) that enables one or more applications executing on the host processor to schedule operations for execution on the PPU 400. In an embodiment, multiple compute applications are simultaneously executed by the PPU 400 and the PPU 400 provides isolation, quality of service (QOS), and independent address spaces for the multiple compute applications. An application may generate instructions (e.g., API calls) that cause the driver kernel to generate one or more tasks for execution by the PPU 400. The driver kernel outputs tasks to one or more streams being processed by the PPU 400. Each task may comprise one or more groups of related threads, referred to herein as a warp. In an embodiment, a warp comprises 32 related threads that may be executed in parallel. Cooperating threads may refer to a plurality of threads including instructions to perform the task and that may exchange data through shared memory. The tasks may be allocated to one or more processing units within a GPC 450 and instructions are scheduled for execution by at least one warp.

The work distribution unit 425 communicates with the one or more GPCs 450 via XBar 470. The XBar 470 is an interconnect network that couples many of the units of the PPU 400 to other units of the PPU 400. For example, the XBar 470 may be configured to couple the work distribution unit 425 to a particular GPC 450. Although not shown explicitly, one or more other units of the PPU 400 may also be connected to the XBar 470 via the hub 430.

The tasks are managed by the scheduler unit 420 and dispatched to a GPC 450 by the work distribution unit 425. The GPC 450 is configured to process the task and generate results. The results may be consumed by other tasks within the GPC 450, routed to a different GPC 450 via the XBar 470, or stored in the memory 404. The results can be written to the memory 404 via the memory partition units 480, which implement a memory interface for reading and writing data to/from the memory 404. The results can be transmitted to another PPU 400 or CPU via the NVLink 410. In an embodiment, the PPU 400 includes a number U of memory partition units 480 that is equal to the number of separate and distinct memory devices of the memory 404 coupled to the PPU 400. Each GPC 450 may include a memory management unit to provide translation of virtual addresses into physical addresses, memory protection, and arbitration of memory requests. In an embodiment, the memory management unit provides one or more translation lookaside buffers (TLBs) for performing translation of virtual addresses into physical addresses in the memory 404.

In an embodiment, the memory partition unit 480 includes a Raster Operations (ROP) unit, a level two (L2) cache, and a memory interface that is coupled to the memory 404. The memory interface may implement 32, 64, 128, 1024-bit data buses, or the like, for high-speed data transfer. The PPU 400 may be connected to up to Y memory devices, such as high bandwidth memory stacks or graphics double-data-rate, version 5, synchronous dynamic random access memory, or other types of persistent storage. In an embodiment, the memory interface implements an HBM2 memory interface and Y equals half U. In an embodiment, the HBM2 memory stacks are located on the same physical package as the PPU 400, providing substantial power and area savings compared with conventional GDDR5 SDRAM systems. In an embodiment, each HBM2 stack includes four memory dies and Y equals 4, with each HBM2 stack including two 128-bit channels per die for a total of 8 channels and a data bus width of 1024 bits.

In an embodiment, the memory 404 supports Single-Error Correcting Double-Error Detecting (SECDED) Error Correction Code (ECC) to protect data. ECC provides higher reliability for compute applications that are sensitive to data corruption. Reliability is especially important in large-scale cluster computing environments where PPUs 400 process very large datasets and/or run applications for extended periods.

In an embodiment, the PPU 400 implements a multi-level memory hierarchy. In an embodiment, the memory partition unit 480 supports a unified memory to provide a single unified virtual address space for CPU and PPU 400 memory, enabling data sharing between virtual memory systems. In an embodiment the frequency of accesses by a PPU 400 to memory located on other processors is traced to ensure that memory pages are moved to the physical memory of the PPU 400 that is accessing the pages more frequently. In an embodiment, the NVLink 410 supports address translation services allowing the PPU 400 to directly access a CPU's page tables and providing full access to CPU memory by the PPU 400.

In an embodiment, copy engines transfer data between multiple PPUs 400 or between PPUs 400 and CPUs. The copy engines can generate page faults for addresses that are not mapped into the page tables. The memory partition unit 480 can then service the page faults, mapping the addresses into the page table, after which the copy engine can perform the transfer. In a conventional system, memory is pinned (e.g., non-pageable) for multiple copy engine operations between multiple processors, substantially reducing the available memory. With hardware page faulting, addresses can be passed to the copy engines without worrying if the memory pages are resident, and the copy process is transparent.

Data from the memory 404 or other system memory may be fetched by the memory partition unit 480 and stored in an L2 cache, which is located on-chip and is shared between the various GPCs 450. As shown, each memory partition unit 480 includes a portion of the L2 cache associated with a corresponding memory 404. Lower level caches may then be implemented in various units within the GPCs 450. For example, each of the processing units within a GPC 450 may implement a level one (L1) cache. The L1 cache is private memory that is dedicated to a particular processing unit. The L2 cache is coupled to the memory interface 470 and the XBar 470 and data from the L2 cache may be fetched and stored in each of the L1 caches for processing.

In an embodiment, the processing units within each GPC 450 implement a SIMD (Single-Instruction, Multiple-Data) architecture where each thread in a group of threads (e.g., a warp) is configured to process a different set of data based on the same set of instructions. All threads in the group of threads execute the same instructions. In another embodiment, the processing unit implements a SIMT (Single-Instruction, Multiple Thread) architecture where each thread in a group of threads is configured to process a different set of data based on the same set of instructions, but where individual threads in the group of threads are allowed to diverge during execution. In an embodiment, a program counter, call stack, and execution state is maintained for each warp, enabling concurrency between warps and serial execution within warps when threads within the warp diverge. In another embodiment, a program counter, call stack, and execution state is maintained for each individual thread, enabling equal concurrency between all threads, within and between warps. When execution state is maintained for each individual thread, threads executing the same instructions may be converged and executed in parallel for maximum efficiency.

Cooperative Groups is a programming model for organizing groups of communicating threads that allows developers to express the granularity at which threads are communicating, enabling the expression of richer, more efficient parallel decompositions. Cooperative launch APIs support synchronization amongst thread blocks for the execution of parallel algorithms. Conventional programming models provide a single, simple construct for synchronizing cooperating threads: a barrier across all threads of a thread block (e.g., the syncthreads( ) function). However, programmers would often like to define groups of threads at smaller than thread block granularities and synchronize within the defined groups to enable greater performance, design flexibility, and software reuse in the form of collective group-wide function interfaces.

Cooperative Groups enables programmers to define groups of threads explicitly at sub-block (e.g., as small as a single thread) and multi-block granularities, and to perform collective operations such as synchronization on the threads in a cooperative group. The programming model supports clean composition across software boundaries, so that libraries and utility functions can synchronize safely within their local context without having to make assumptions about convergence. Cooperative Groups primitives enable new patterns of cooperative parallelism, including producer-consumer parallelism, opportunistic parallelism, and global synchronization across an entire grid of thread blocks.

Each processing unit includes a large number (e.g., 128, etc.) of distinct processing cores (e.g., functional units) that may be fully-pipelined, single-precision, double-precision, and/or mixed precision and include a floating point arithmetic logic unit and an integer arithmetic logic unit. In an embodiment, the floating point arithmetic logic units implement the IEEE 754-2008 standard for floating point arithmetic. In an embodiment, the cores include 64 single-precision (32-bit) floating point cores, 64 integer cores, 32 double-precision (64-bit) floating point cores, and 8 tensor cores.

Tensor cores configured to perform matrix operations. In particular, the tensor cores are configured to perform deep learning matrix arithmetic, such as GEMM (matrix-matrix multiplication) for convolution operations during neural network training and inferencing. In an embodiment, each tensor core operates on a 4×4 matrix and performs a matrix multiply and accumulate operation D=A′B+C, where A, B, C, and D are 4×4 matrices.

In an embodiment, the matrix multiply inputs A and B may be integer, fixed-point, or floating point matrices, while the accumulation matrices C and D may be integer, fixed-point, or floating point matrices of equal or higher bitwidths. In an embodiment, tensor cores operate on one, four, or eight bit integer input data with 32-bit integer accumulation. The 8-bit integer matrix multiply requires 1024 operations and results in a full precision product that is then accumulated using 32-bit integer addition with the other intermediate products for a 8×8×16 matrix multiply. In an embodiment, tensor Cores operate on 16-bit floating point input data with 32-bit floating point accumulation. The 16-bit floating point multiply requires 64 operations and results in a full precision product that is then accumulated using 32-bit floating point addition with the other intermediate products for a 4×4×4 matrix multiply. In practice, Tensor Cores are used to perform much larger two-dimensional or higher dimensional matrix operations, built up from these smaller elements. An API, such as CUDA 9 C++ API, exposes specialized matrix load, matrix multiply and accumulate, and matrix store operations to efficiently use Tensor Cores from a CUDA-C++ program. At the CUDA level, the warp-level interface assumes 16×16 size matrices spanning all 32 threads of the warp.

Each processing unit may also comprise M special function units (SFUs) that perform special functions (e.g., attribute evaluation, reciprocal square root, and the like). In an embodiment, the SFUs may include a tree traversal unit configured to traverse a hierarchical tree data structure. In an embodiment, the SFUs may include texture unit configured to perform texture map filtering operations. In an embodiment, the texture units are configured to load texture maps (e.g., a 2D array of texels) from the memory 404 and sample the texture maps to produce sampled texture values for use in shader programs executed by the processing unit. In an embodiment, the texture maps are stored in shared memory that may comprise or include an L1 cache. The texture units implement texture operations such as filtering operations using mip-maps (e.g., texture maps of varying levels of detail). In an embodiment, each processing unit includes two texture units.

Each processing unit also comprises N load store units (LSUs) that implement load and store operations between the shared memory and the register file. Each processing unit includes an interconnect network that connects each of the cores to the register file and the LSU to the register file, shared memory. In an embodiment, the interconnect network is a crossbar that can be configured to connect any of the cores to any of the registers in the register file and connect the LSUs to the register file and memory locations in shared memory.

The shared memory is an array of on-chip memory that allows for data storage and communication between the processing units and between threads within a processing unit. In an embodiment, the shared memory comprises 128 KB of storage capacity and is in the path from each of the processing units to the memory partition unit 480. The shared memory can be used to cache reads and writes. One or more of the shared memory, L1 cache, L2 cache, and memory 404 are backing stores.

Combining data cache and shared memory functionality into a single memory block provides the best overall performance for both types of memory accesses. The capacity is usable as a cache by programs that do not use shared memory. For example, if shared memory is configured to use half of the capacity, texture and load/store operations can use the remaining capacity. Integration within the shared memory enables the shared memory to function as a high-throughput conduit for streaming data while simultaneously providing high-bandwidth and low-latency access to frequently reused data.

When configured for general purpose parallel computation, a simpler configuration can be used compared with graphics processing. Specifically, fixed function graphics processing units, are bypassed, creating a much simpler programming model. In the general purpose parallel computation configuration, the work distribution unit 425 assigns and distributes blocks of threads directly to the processing units within the GPCs 450. Threads execute the same program, using a unique thread ID in the calculation to ensure each thread generates unique results, using the processing unit(s) to execute the program and perform calculations, shared memory to communicate between threads, and the LSU to read and write global memory through the shared memory and the memory partition unit 480. When configured for general purpose parallel computation, the processing units can also write commands that the scheduler unit 420 can use to launch new work on the processing units.

The PPUs 400 may each include, and/or be configured to perform functions of, one or more processing cores and/or components thereof, such as Tensor Cores (TCs), Tensor Processing Units (TPUs), Pixel Visual Cores (PVCs), Ray Tracing (RT) Cores, Vision Processing Units (VPUs), Graphics Processing Clusters (GPCs), Texture Processing Clusters (TPCs), Streaming Multiprocessors (SMs), Tree Traversal Units (TTUs), Artificial Intelligence Accelerators (AIAs), Deep Learning Accelerators (DLAs), Arithmetic-Logic Units (ALUs), Application-Specific Integrated Circuits (ASICs), Floating Point Units (FPUs), input/output (I/O) elements, peripheral component interconnect (PCI) or peripheral component interconnect express (PCIe) elements, and/or the like.

The PPU 400 may be included in a desktop computer, a laptop computer, a tablet computer, servers, supercomputers, a smart-phone (e.g., a wireless, hand-held device), personal digital assistant (PDA), a digital camera, a vehicle, a head mounted display, a hand-held electronic device, and the like. In an embodiment, the PPU 400 is embodied on a single semiconductor substrate. In another embodiment, the PPU 400 is included in a system-on-a-chip (SoC) along with one or more other devices such as additional PPUs 400, the memory 404, a reduced instruction set computer (RISC) CPU, a memory management unit (MMU), a digital-to-analog converter (DAC), and the like.

In an embodiment, the PPU 400 may be included on a graphics card that includes one or more memory devices. The graphics card may be configured to interface with a PCIe slot on a motherboard of a desktop computer. In yet another embodiment, the PPU 400 may be an integrated graphics processing unit (iGPU) or parallel processor included in the chipset of the motherboard. In yet another embodiment, the PPU 400 may be realized in reconfigurable hardware. In yet another embodiment, parts of the PPU 400 may be realized in reconfigurable hardware.

### Exemplary Computing System

Systems with multiple GPUs and CPUs are used in a variety of industries as developers expose and leverage more parallelism in applications such as artificial intelligence computing. High-performance GPU-accelerated systems with tens to many thousands of compute nodes are deployed in data centers, research facilities, and supercomputers to solve ever larger problems. As the number of processing devices within the high-performance systems increases, the communication and data transfer mechanisms need to scale to support the increased bandwidth.

FIG. 5A is a conceptual diagram of a processing system 500 implemented using the PPU 400 of FIG. 4, in accordance with an embodiment. The exemplary system 500 may be configured to implement one or more of the methods 250 and 340 shown in FIGS. 2D and 3C, respectively. The processing system 500 includes a CPU 530, switch 510, and multiple PPUs 400, and respective memories 404.

The NVLink 410 provides high-speed communication links between each of the PPUs 400. Although a particular number of NVLink 410 and interconnect 402 connections are illustrated in FIG. 5B, the number of connections to each PPU 400 and the CPU 530 may vary. The switch 510 interfaces between the interconnect 402 and the CPU 530. The PPUs 400, memories 404, and NVLinks 410 may be situated on a single semiconductor platform to form a parallel processing module 525. In an embodiment, the switch 510 supports two or more protocols to interface between various different connections and/or links.

In another embodiment (not shown), the NVLink 410 provides one or more high-speed communication links between each of the PPUs 400 and the CPU 530 and the switch 510 interfaces between the interconnect 402 and each of the PPUs 400. The PPUs 400, memories 404, and interconnect 402 may be situated on a single semiconductor platform to form a parallel processing module 525. In yet another embodiment (not shown), the interconnect 402 provides one or more communication links between each of the PPUs 400 and the CPU 530 and the switch 510 interfaces between each of the PPUs 400 using the NVLink 410 to provide one or more high-speed communication links between the PPUs 400. In another embodiment (not shown), the NVLink 410 provides one or more high-speed communication links between the PPUs 400 and the CPU 530 through the switch 510. In yet another embodiment (not shown), the interconnect 402 provides one or more communication links between each of the PPUs 400 directly. One or more of the NVLink 410 high-speed communication links may be implemented as a physical NVLink interconnect or either an on-chip or on-die interconnect using the same protocol as the NVLink 410.

In the context of the present description, a single semiconductor platform may refer to a sole unitary semiconductor-based integrated circuit fabricated on a die or chip. It should be noted that the term single semiconductor platform may also refer to multi-chip modules with increased connectivity which simulate on-chip operation and make substantial improvements over utilizing a conventional bus implementation. Of course, the various circuits or devices may also be situated separately or in various combinations of semiconductor platforms per the desires of the user. Alternately, the parallel processing module 525 may be implemented as a circuit board substrate and each of the PPUs 400 and/or memories 404 may be packaged devices. In an embodiment, the CPU 530, switch 510, and the parallel processing module 525 are situated on a single semiconductor platform.

In an embodiment, the signaling rate of each NVLink 410 is 20 to 25 Gigabits/second and each PPU 400 includes six NVLink 410 interfaces (as shown in FIG. 5A, five NVLink 410 interfaces are included for each PPU 400). Each NVLink 410 provides a data transfer rate of 25 Gigabytes/second in each direction, with six links providing 400 Gigabytes/second. The NVLinks 410 can be used exclusively for PPU-to-PPU communication as shown in FIG. 5A, or some combination of PPU-to-PPU and PPU-to-CPU, when the CPU 530 also includes one or more NVLink 410 interfaces.

In an embodiment, the NVLink 410 allows direct load/store/atomic access from the CPU 530 to each PPU's 400 memory 404. In an embodiment, the NVLink 410 supports coherency operations, allowing data read from the memories 404 to be stored in the cache hierarchy of the CPU 530, reducing cache access latency for the CPU 530. In an embodiment, the NVLink 410 includes support for Address Translation Services (ATS), allowing the PPU 400 to directly access page tables within the CPU 530. One or more of the NVLinks 410 may also be configured to operate in a low-power mode.

FIG. 5B illustrates an exemplary system 565 in which the various architecture and/or functionality of the various previous embodiments may be implemented. The exemplary system 565 may be configured to implement one or more of the methods the methods 250 and 340 shown in FIGS. 2D and 3C, respectively.

As shown, a system 565 is provided including at least one central processing unit 530 that is connected to a communication bus 575. The communication bus 575 may directly or indirectly couple one or more of the following devices: main memory 540, network interface 535, CPU(s) 530, display device(s) 545, input device(s) 560, switch 510, and parallel processing system 525. The communication bus 575 may be implemented using any suitable protocol and may represent one or more links or busses, such as an address bus, a data bus, a control bus, or a combination thereof. The communication bus 575 may include one or more bus or link types, such as an industry standard architecture (ISA) bus, an extended industry standard architecture (EISA) bus, a video electronics standards association (VESA) bus, a peripheral component interconnect (PCI) bus, a peripheral component interconnect express (PCIe) bus, HyperTransport, and/or another type of bus or link. In some embodiments, there are direct connections between components. As an example, the CPU(s) 530 may be directly connected to the main memory 540. Further, the CPU(s) 530 may be directly connected to the parallel processing system 525. Where there is direct, or point-to-point connection between components, the communication bus 575 may include a PCIe link to carry out the connection. In these examples, a PCI bus need not be included in the system 565.

Although the various blocks of FIG. 5B are shown as connected via the communication bus 575 with lines, this is not intended to be limiting and is for clarity only. For example, in some embodiments, a presentation component, such as display device(s) 545, may be considered an I/O component, such as input device(s) 560 (e.g., if the display is a touch screen). As another example, the CPU(s) 530 and/or parallel processing system 525 may include memory (e.g., the main memory 540 may be representative of a storage device in addition to the parallel processing system 525, the CPUs 530, and/or other components). In other words, the computing device of FIG. 5B is merely illustrative. Distinction is not made between such categories as “workstation,” “server,” “laptop,” “desktop,” “tablet,” “client device,” “mobile device,” “hand-held device,” “game console,” “electronic control unit (ECU),” “virtual reality system,” and/or other device or system types, as all are contemplated within the scope of the computing device of FIG. 5B.

The system 565 also includes a main memory 540. Control logic (software) and data are stored in the main memory 540 which may take the form of a variety of computer-readable media. The computer-readable media may be any available media that may be accessed by the system 565. The computer-readable media may include both volatile and nonvolatile media, and removable and non-removable media. By way of example, and not limitation, the computer-readable media may comprise computer-storage media and communication media.

The computer-storage media may include both volatile and nonvolatile media and/or removable and non-removable media implemented in any method or technology for storage of information such as computer-readable instructions, data structures, program modules, and/or other data types. For example, the main memory 540 may store computer-readable instructions (e.g., that represent a program(s) and/or a program element(s), such as an operating system. Computer-storage media may include, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which may be used to store the desired information and which may be accessed by system 565. As used herein, computer storage media does not comprise signals per se.

The computer storage media may embody computer-readable instructions, data structures, program modules, and/or other data types in a modulated data signal such as a carrier wave or other transport mechanism and includes any information delivery media. The term “modulated data signal” may refer to a signal that has one or more of its characteristics set or changed in such a manner as to encode information in the signal. By way of example, and not limitation, the computer storage media may include wired media such as a wired network or direct-wired connection, and wireless media such as acoustic, RF, infrared and other wireless media. Combinations of any of the above should also be included within the scope of computer-readable media.

Computer programs, when executed, enable the system 565 to perform various functions. The CPU(s) 530 may be configured to execute at least some of the computer-readable instructions to control one or more components of the system 565 to perform one or more of the methods and/or processes described herein. The CPU(s) 530 may each include one or more cores (e.g., one, two, four, eight, twenty-eight, seventy-two, etc.) that are capable of handling a multitude of software threads simultaneously. The CPU(s) 530 may include any type of processor, and may include different types of processors depending on the type of system 565 implemented (e.g., processors with fewer cores for mobile devices and processors with more cores for servers). For example, depending on the type of system 565, the processor may be an Advanced RISC Machines (ARM) processor implemented using Reduced Instruction Set Computing (RISC) or an x86 processor implemented using Complex Instruction Set Computing (CISC). The system 565 may include one or more CPUs 530 in addition to one or more microprocessors or supplementary co-processors, such as math co-processors.

In addition to or alternatively from the CPU(s) 530, the parallel processing module 525 may be configured to execute at least some of the computer-readable instructions to control one or more components of the system 565 to perform one or more of the methods and/or processes described herein. The parallel processing module 525 may be used by the system 565 to render graphics (e.g., 3D graphics) or perform general purpose computations. For example, the parallel processing module 525 may be used for General-Purpose computing on GPUs (GPGPU). In embodiments, the CPU(s) 530 and/or the parallel processing module 525 may discretely or jointly perform any combination of the methods, processes and/or portions thereof.

The system 565 also includes input device(s) 560, the parallel processing system 525, and display device(s) 545. The display device(s) 545 may include a display (e.g., a monitor, a touch screen, a television screen, a heads-up-display (HUD), other display types, or a combination thereof), speakers, and/or other presentation components. The display device(s) 545 may receive data from other components (e.g., the parallel processing system 525, the CPU(s) 530, etc.), and output the data (e.g., as an image, video, sound, etc.).

The network interface 535 may enable the system 565 to be logically coupled to other devices including the input devices 560, the display device(s) 545, and/or other components, some of which may be built in to (e.g., integrated in) the system 565. Illustrative input devices 560 include a microphone, mouse, keyboard, joystick, game pad, game controller, satellite dish, scanner, printer, wireless device, etc. The input devices 560 may provide a natural user interface (NUI) that processes air gestures, voice, or other physiological inputs generated by a user. In some instances, inputs may be transmitted to an appropriate network element for further processing. An NUI may implement any combination of speech recognition, stylus recognition, facial recognition, biometric recognition, gesture recognition both on screen and adjacent to the screen, air gestures, head and eye tracking, and touch recognition (as described in more detail below) associated with a display of the system 565. The system 565 may be include depth cameras, such as stereoscopic camera systems, infrared camera systems, RGB camera systems, touchscreen technology, and combinations of these, for gesture detection and recognition. Additionally, the system 565 may include accelerometers or gyroscopes (e.g., as part of an inertia measurement unit (IMU)) that enable detection of motion. In some examples, the output of the accelerometers or gyroscopes may be used by the system 565 to render immersive augmented reality or virtual reality.

Further, the system 565 may be coupled to a network (e.g., a telecommunications network, local area network (LAN), wireless network, wide area network (WAN) such as the Internet, peer-to-peer network, cable network, or the like) through a network interface 535 for communication purposes. The system 565 may be included within a distributed network and/or cloud computing environment.

The network interface 535 may include one or more receivers, transmitters, and/or transceivers that enable the system 565 to communicate with other computing devices via an electronic communication network, included wired and/or wireless communications. The network interface 535 may be implemented as a network interface controller (NIC) that includes one or more data processing units (DPUs) to perform operations such as (for example and without limitation) packet parsing and accelerating network processing and communication. The network interface 535 may include components and functionality to enable communication over any of a number of different networks, such as wireless networks (e.g., Wi-Fi, Z-Wave, Bluetooth, Bluetooth LE, ZigBee, etc.), wired networks (e.g., communicating over Ethernet or InfiniBand), low-power wide-area networks (e.g., LoRaWAN, SigFox, etc.), and/or the Internet.

The system 565 may also include a secondary storage (not shown). The secondary storage includes, for example, a hard disk drive and/or a removable storage drive, representing a floppy disk drive, a magnetic tape drive, a compact disk drive, digital versatile disk (DVD) drive, recording device, universal serial bus (USB) flash memory. The removable storage drive reads from and/or writes to a removable storage unit in a well-known manner. The system 565 may also include a hard-wired power supply, a battery power supply, or a combination thereof (not shown). The power supply may provide power to the system 565 to enable the components of the system 565 to operate.

Each of the foregoing modules and/or devices may even be situated on a single semiconductor platform to form the system 565. Alternately, the various modules may also be situated separately or in various combinations of semiconductor platforms per the desires of the user. While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

### Example Network Environments

Network environments suitable for use in implementing embodiments of the disclosure may include one or more client devices, servers, network attached storage (NAS), other backend devices, and/or other device types. The client devices, servers, and/or other device types (e.g., each device) may be implemented on one or more instances of the processing system 500 of FIG. 5A and/or exemplary system 565 of FIG. 5B—e.g., each device may include similar components, features, and/or functionality of the processing system 500 and/or exemplary system 565.

Components of a network environment may communicate with each other via a network(s), which may be wired, wireless, or both. The network may include multiple networks, or a network of networks. By way of example, the network may include one or more Wide Area Networks (WANs), one or more Local Area Networks (LANs), one or more public networks such as the Internet and/or a public switched telephone network (PSTN), and/or one or more private networks. Where the network includes a wireless telecommunications network, components such as a base station, a communications tower, or even access points (as well as other components) may provide wireless connectivity.

Compatible network environments may include one or more peer-to-peer network environments—in which case a server may not be included in a network environment—and one or more client-server network environments—in which case one or more servers may be included in a network environment. In peer-to-peer network environments, functionality described herein with respect to a server(s) may be implemented on any number of client devices.

In at least one embodiment, a network environment may include one or more cloud-based network environments, a distributed computing environment, a combination thereof, etc. A cloud-based network environment may include a framework layer, a job scheduler, a resource manager, and a distributed file system implemented on one or more of servers, which may include one or more core network servers and/or edge servers. A framework layer may include a framework to support software of a software layer and/or one or more application(s) of an application layer. The software or application(s) may respectively include web-based service software or applications. In embodiments, one or more of the client devices may use the web-based service software or applications (e.g., by accessing the service software and/or applications via one or more application programming interfaces (APIs)). The framework layer may be, but is not limited to, a type of free and open-source software web application framework such as that may use a distributed file system for large-scale data processing (e.g., “big data”).

A cloud-based network environment may provide cloud computing and/or cloud storage that carries out any combination of computing and/or data storage functions described herein (or one or more portions thereof). Any of these various functions may be distributed over multiple locations from central or core servers (e.g., of one or more data centers that may be distributed across a state, a region, a country, the globe, etc.). If a connection to a user (e.g., a client device) is relatively close to an edge server(s), a core server(s) may designate at least a portion of the functionality to the edge server(s). A cloud-based network environment may be private (e.g., limited to a single organization), may be public (e.g., available to many organizations), and/or a combination thereof (e.g., a hybrid cloud environment).

The client device(s) may include at least some of the components, features, and functionality of the example processing system 500 of FIG. 5A and/or exemplary system 565 of FIG. 5B. By way of example and not limitation, a client device may be embodied as a Personal Computer (PC), a laptop computer, a mobile device, a smartphone, a tablet computer, a smart watch, a wearable computer, a Personal Digital Assistant (PDA), an MP3 player, a virtual reality headset, a Global Positioning System (GPS) or device, a video player, a video camera, a surveillance device or system, a vehicle, a boat, a flying vessel, a virtual machine, a drone, a robot, a handheld communications device, a hospital device, a gaming device or system, an entertainment system, a vehicle computer system, an embedded system controller, a remote control, an appliance, a consumer electronic device, a workstation, an edge device, any combination of these delineated devices, or any other suitable device.

### Machine Learning

Deep neural networks (DNNs) developed on processors, such as the PPU 400 have been used for diverse use cases, from self-driving cars to faster drug development, from automatic image captioning in online image databases to smart real-time language translation in video chat applications. Deep learning is a technique that models the neural learning process of the human brain, continually learning, continually getting smarter, and delivering more accurate results more quickly over time. A child is initially taught by an adult to correctly identify and classify various shapes, eventually being able to identify shapes without any coaching. Similarly, a deep learning or neural learning system needs to be trained in object recognition and classification for it get smarter and more efficient at identifying basic objects, occluded objects, etc., while also assigning context to objects.

At the simplest level, neurons in the human brain look at various inputs that are received, importance levels are assigned to each of these inputs, and output is passed on to other neurons to act upon. An artificial neuron or perceptron is the most basic model of a neural network. In one example, a perceptron may receive one or more inputs that represent various features of an object that the perceptron is being trained to recognize and classify, and each of these features is assigned a certain weight based on the importance of that feature in defining the shape of an object.

A deep neural network (DNN) model includes multiple layers of many connected nodes (e.g., perceptrons, Boltzmann machines, radial basis functions, convolutional layers, etc.) that can be trained with enormous amounts of input data to quickly solve complex problems with high accuracy. In one example, a first layer of the DNN model breaks down an input image of an automobile into various sections and looks for basic patterns such as lines and angles. The second layer assembles the lines to look for higher level patterns such as wheels, windshields, and mirrors. The next layer identifies the type of vehicle, and the final few layers generate a label for the input image, identifying the model of a specific automobile brand.

Once the DNN is trained, the DNN can be deployed and used to identify and classify objects or patterns in a process known as inference. Examples of inference (the process through which a DNN extracts useful information from a given input) include identifying handwritten numbers on checks deposited into ATM machines, identifying images of friends in photos, delivering movie recommendations to over fifty million users, identifying and classifying different types of automobiles, pedestrians, and road hazards in driverless cars, or translating human speech in real-time.

During training, data flows through the DNN in a forward propagation phase until a prediction is produced that indicates a label corresponding to the input. If the neural network does not correctly label the input, then errors between the correct label and the predicted label are analyzed, and the weights are adjusted for each feature during a backward propagation phase until the DNN correctly labels the input and other inputs in a training dataset. Training complex neural networks requires massive amounts of parallel computing performance, including floating-point multiplications and additions that are supported by the PPU 400. Inferencing is less compute-intensive than training, being a latency-sensitive process where a trained neural network is applied to new inputs it has not seen before to classify images, detect emotions, identify recommendations, recognize and translate speech, and generally infer new information.

Neural networks rely heavily on matrix math operations, and complex multi-layered networks require tremendous amounts of floating-point performance and bandwidth for both efficiency and speed. With thousands of processing cores, optimized for matrix math operations, and delivering tens to hundreds of TFLOPS of performance, the PPU 400 is a computing platform capable of delivering performance required for deep neural network-based artificial intelligence and machine learning applications.

Furthermore, images generated applying one or more of the techniques disclosed herein may be used to train, test, or certify DNNs used to recognize objects and environments in the real world. Such images may include scenes of roadways, factories, buildings, urban settings, rural settings, humans, animals, and any other physical object or real-world setting. Such images may be used to train, test, or certify DNNs that are employed in machines or robots to manipulate, handle, or modify physical objects in the real world. Furthermore, such images may be used to train, test, or certify DNNs that are employed in autonomous vehicles to navigate and move the vehicles through the real world. Additionally, images generated applying one or more of the techniques disclosed herein may be used to convey information to users of such machines, robots, and vehicles.

FIG. 5C illustrates components of an exemplary system 555 that can be used to train and utilize machine learning, in accordance with at least one embodiment. As will be discussed, various components can be provided by various combinations of computing devices and resources, or a single computing system, which may be under control of a single entity or multiple entities. Further, aspects may be triggered, initiated, or requested by different entities. In at least one embodiment training of a neural network might be instructed by a provider associated with provider environment 506, while in at least one embodiment training might be requested by a customer or other user having access to a provider environment through a client device 502 or other such resource. In at least one embodiment, training data (or data to be analyzed by a trained neural network) can be provided by a provider, a user, or a third party content provider 524. In at least one embodiment, client device 502 may be a vehicle or object that is to be navigated on behalf of a user, for example, which can submit requests and/or receive instructions that assist in navigation of a device.

In at least one embodiment, requests are able to be submitted across at least one network 504 to be received by a provider environment 506. In at least one embodiment, a client device may be any appropriate electronic and/or computing devices enabling a user to generate and send such requests, such as, but not limited to, desktop computers, notebook computers, computer servers, smartphones, tablet computers, gaming consoles (portable or otherwise), computer processors, computing logic, and set-top boxes. Network(s) 504 can include any appropriate network for transmitting a request or other such data, as may include Internet, an intranet, an Ethernet, a cellular network, a local area network (LAN), a wide area network (WAN), a personal area network (PAN), an ad hoc network of direct wireless connections among peers, and so on.

In at least one embodiment, requests can be received at an interface layer 508, which can forward data to a training and inference manager 532, in this example. The training and inference manager 532 can be a system or service including hardware and software for managing requests and service corresponding data or content, in at least one embodiment, the training and inference manager 532 can receive a request to train a neural network, and can provide data for a request to a training module 512. In at least one embodiment, training module 512 can select an appropriate model or neural network to be used, if not specified by the request, and can train a model using relevant training data. In at least one embodiment, training data can be a batch of data stored in a training data repository 514, received from client device 502, or obtained from a third party provider 524. In at least one embodiment, training module 512 can be responsible for training data. A neural network can be any appropriate network, such as a recurrent neural network (RNN) or convolutional neural network (CNN). Once a neural network is trained and successfully evaluated, a trained neural network can be stored in a model repository 516, for example, that may store different models or networks for users, applications, or services, etc. In at least one embodiment, there may be multiple models for a single application or entity, as may be utilized based on a number of different factors.

In at least one embodiment, at a subsequent point in time, a request may be received from client device 502 (or another such device) for content (e.g., path determinations) or data that is at least partially determined or impacted by a trained neural network. This request can include, for example, input data to be processed using a neural network to obtain one or more inferences or other output values, classifications, or predictions, or for at least one embodiment, input data can be received by interface layer 508 and directed to inference module 518, although a different system or service can be used as well. In at least one embodiment, inference module 518 can obtain an appropriate trained network, such as a trained deep neural network (DNN) as discussed herein, from model repository 516 if not already stored locally to inference module 518. Inference module 518 can provide data as input to a trained network, which can then generate one or more inferences as output. This may include, for example, a classification of an instance of input data. In at least one embodiment, inferences can then be transmitted to client device 502 for display or other communication to a user. In at least one embodiment, context data for a user may also be stored to a user context data repository 522, which may include data about a user which may be useful as input to a network in generating inferences, or determining data to return to a user after obtaining instances. In at least one embodiment, relevant data, which may include at least some of input or inference data, may also be stored to a local database 534 for processing future requests. In at least one embodiment, a user can use account information or other information to access resources or functionality of a provider environment. In at least one embodiment, if permitted and available, user data may also be collected and used to further train models, in order to provide more accurate inferences for future requests. In at least one embodiment, requests may be received through a user interface to a machine learning application 526 executing on client device 502, and results displayed through a same interface. A client device can include resources such as a processor 528 and memory 562 for generating a request and processing results or a response, as well as at least one data storage element 552 for storing data for machine learning application 526.

In at least one embodiment a processor 528 (or a processor of training module 512 or inference module 518) will be a central processing unit (CPU). As mentioned, however, resources in such environments can utilize GPUs to process data for at least certain types of requests. With thousands of cores, GPUs, such as PPU 400 are designed to handle substantial parallel workloads and, therefore, have become popular in deep learning for training neural networks and generating predictions. While use of GPUs for offline builds has enabled faster training of larger and more complex models, generating predictions offline implies that either request-time input features cannot be used or predictions must be generated for all permutations of features and stored in a lookup table to serve real-time requests. If a deep learning framework supports a CPU-mode and a model is small and simple enough to perform a feed-forward on a CPU with a reasonable latency, then a service on a CPU instance could host a model. In this case, training can be done offline on a GPU and inference done in real-time on a CPU. If a CPU approach is not viable, then a service can run on a GPU instance. Because GPUs have different performance and cost characteristics than CPUs, however, running a service that offloads a runtime algorithm to a GPU can require it to be designed differently from a CPU based service.

In at least one embodiment, video data can be provided from client device 502 for enhancement in provider environment 506. In at least one embodiment, video data can be processed for enhancement on client device 502. In at least one embodiment, video data may be streamed from a third party content provider 524 and enhanced by third party content provider 524, provider environment 506, or client device 502. In at least one embodiment, video data can be provided from client device 502 for use as training data in provider environment 506.

In at least one embodiment, supervised and/or unsupervised training can be performed by the client device 502 and/or the provider environment 506. In at least one embodiment, a set of training data 514 (e.g., classified or labeled data) is provided as input to function as training data. In at least one embodiment, training data can include instances of at least one type of object for which a neural network is to be trained, as well as information that identifies that type of object. In at least one embodiment, training data might include a set of images that each includes a representation of a type of object, where each image also includes, or is associated with, a label, metadata, classification, or other piece of information identifying a type of object represented in a respective image. Various other types of data may be used as training data as well, as may include text data, audio data, video data, and so on. In at least one embodiment, training data 514 is provided as training input to a training module 512. In at least one embodiment, training module 512 can be a system or service that includes hardware and software, such as one or more computing devices executing a training application, for training a neural network (or other model or algorithm, etc.). In at least one embodiment, training module 512 receives an instruction or request indicating a type of model to be used for training, in at least one embodiment, a model can be any appropriate statistical model, network, or algorithm useful for such purposes, as may include an artificial neural network, deep learning algorithm, learning classifier, Bayesian network, and so on. In at least one embodiment, training module 512 can select an initial model, or other untrained model, from an appropriate repository 516 and utilize training data 514 to train a model, thereby generating a trained model (e.g., trained deep neural network) that can be used to classify similar types of data, or generate other such inferences. In at least one embodiment where training data is not used, an appropriate initial model can still be selected for training on input data per training module 512.

In at least one embodiment, a model can be trained in a number of different ways, as may depend in part upon a type of model selected. In at least one embodiment, a machine learning algorithm can be provided with a set of training data, where a model is a model artifact created by a training process. In at least one embodiment, each instance of training data contains a correct answer (e.g., classification), which can be referred to as a target or target attribute. In at least one embodiment, a learning algorithm finds patterns in training data that map input data attributes to a target, an answer to be predicted, and a machine learning model is output that captures these patterns. In at least one embodiment, a machine learning model can then be used to obtain predictions on new data for which a target is not specified.

In at least one embodiment, training and inference manager 532 can select from a set of machine learning models including binary classification, multiclass classification, generative, and regression models. In at least one embodiment, a type of model to be used can depend at least in part upon a type of target to be predicted.

### Graphics Processing Pipeline

In an embodiment, the PPU 400 comprises a graphics processing unit (GPU). The PPU 400 is configured to receive commands that specify shader programs for processing graphics data. Graphics data may be defined as a set of primitives such as points, lines, triangles, quads, triangle strips, and the like. Typically, a primitive includes data that specifies a number of vertices for the primitive (e.g., in a model-space coordinate system) as well as attributes associated with each vertex of the primitive. The PPU 400 can be configured to process the graphics primitives to generate a frame buffer (e.g., pixel data for each of the pixels of the display).

An application writes model data for a scene (e.g., a collection of vertices and attributes) to a memory such as a system memory or memory 404. The model data defines each of the objects that may be visible on a display. The application then makes an API call to the driver kernel that requests the model data to be rendered and displayed. The driver kernel reads the model data and writes commands to the one or more streams to perform operations to process the model data. The commands may reference different shader programs to be implemented on the processing units within the PPU 400 including one or more of a vertex shader, hull shader, domain shader, geometry shader, and a pixel shader. For example, one or more of the processing units may be configured to execute a vertex shader program that processes a number of vertices defined by the model data. In an embodiment, the different processing units may be configured to execute different shader programs concurrently. For example, a first subset of processing units may be configured to execute a vertex shader program while a second subset of processing units may be configured to execute a pixel shader program. The first subset of processing units processes vertex data to produce processed vertex data and writes the processed vertex data to the L2 cache and/or the memory 404. After the processed vertex data is rasterized (e.g., transformed from three-dimensional data into two-dimensional data in screen space) to produce fragment data, the second subset of processing units executes a pixel shader to produce processed fragment data, which is then blended with other processed fragment data and written to the frame buffer in memory 404. The vertex shader program and pixel shader program may execute concurrently, processing different data from the same scene in a pipelined fashion until all of the model data for the scene has been rendered to the frame buffer. Then, the contents of the frame buffer are transmitted to a display controller for display on a display device.

Images generated applying one or more of the techniques disclosed herein may be displayed on a monitor or other display device. In some embodiments, the display device may be coupled directly to the system or processor generating or rendering the images. In other embodiments, the display device may be coupled indirectly to the system or processor such as via a network. Examples of such networks include the Internet, mobile telecommunications networks, a WIFI network, as well as any other wired and/or wireless networking system. When the display device is indirectly coupled, the images generated by the system or processor may be streamed over the network to the display device. Such streaming allows, for example, video games or other applications, which render images, to be executed on a server, a data center, or in a cloud-based computing environment and the rendered images to be transmitted and displayed on one or more user devices (such as a computer, video game console, smartphone, other mobile device, etc.) that are physically separate from the server or data center. Hence, the techniques disclosed herein can be applied to enhance the images that are streamed and to enhance services that stream images such as NVIDIA GeForce Now (GFN), Google Stadia, and the like.

### Example Streaming System

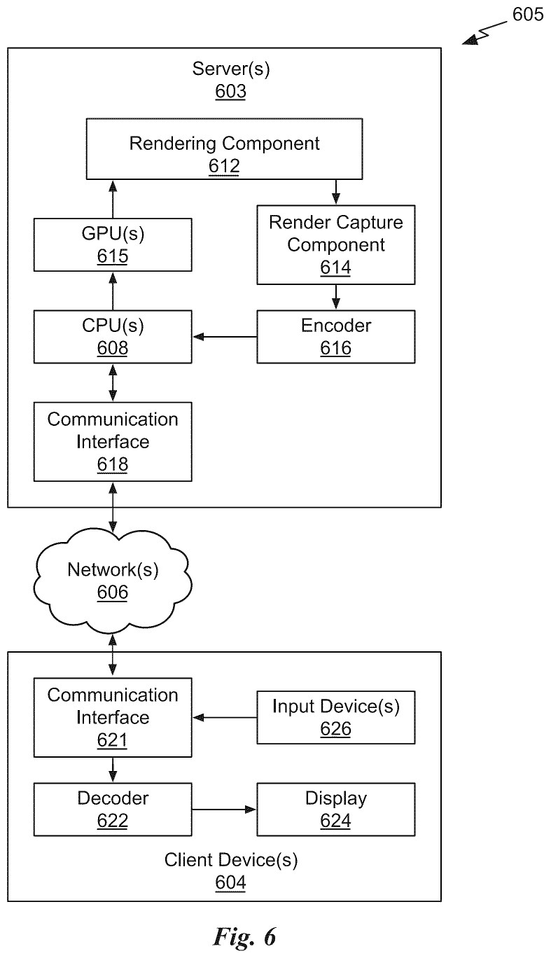

FIG. 6 is an example system diagram for a streaming system 605, in accordance with some embodiments of the present disclosure. FIG. 6 includes server(s) 603 (which may include similar components, features, and/or functionality to the example processing system 500 of FIG. 5A and/or exemplary system 565 of FIG. 5B), client device(s) 604 (which may include similar components, features, and/or functionality to the example processing system 500 of FIG. 5A and/or exemplary system 565 of FIG. 5B), and network(s) 606 (which may be similar to the network(s) described herein). In some embodiments of the present disclosure, the system 605 may be implemented.

In an embodiment, the streaming system 605 is a game streaming system and the server(s) 603 are game server(s). In the system 605, for a game session, the client device(s) 604 may only receive input data in response to inputs to the input device(s) 626, transmit the input data to the server(s) 603, receive encoded display data from the server(s) 603, and display the display data on the display 624. As such, the more computationally intense computing and processing is offloaded to the server(s) 603 (e.g., rendering—in particular ray or path tracing—for graphical output of the game session is executed by the GPU(s) 615 of the server(s) 603). In other words, the game session is streamed to the client device(s) 604 from the server(s) 603, thereby reducing the requirements of the client device(s) 604 for graphics processing and rendering.

For example, with respect to an instantiation of a game session, a client device 604 may be displaying a frame of the game session on the display 624 based on receiving the display data from the server(s) 603. The client device 604 may receive an input to one of the input device(s) 626 and generate input data in response. The client device 604 may transmit the input data to the server(s) 603 via the communication interface 621 and over the network(s) 606 (e.g., the Internet), and the server(s) 603 may receive the input data via the communication interface 618. The CPU(s) 608 may receive the input data, process the input data, and transmit data to the GPU(s) 615 that causes the GPU(s) 615 to generate a rendering of the game session. For example, the input data may be representative of a movement of a character of the user in a game, firing a weapon, reloading, passing a ball, turning a vehicle, etc. The rendering component 612 may render the game session (e.g., representative of the result of the input data) and the render capture component 614 may capture the rendering of the game session as display data (e.g., as image data capturing the rendered frame of the game session). The rendering of the game session may include ray or path-traced lighting and/or shadow effects, computed using one or more parallel processing units-such as GPUs, which may further employ the use of one or more dedicated hardware accelerators or processing cores to perform ray or path-tracing techniques-of the server(s) 603. The encoder 616 may then encode the display data to generate encoded display data and the encoded display data may be transmitted to the client device 604 over the network(s) 606 via the communication interface 618. The client device 604 may receive the encoded display data via the communication interface 621 and the decoder 622 may decode the encoded display data to generate the display data. The client device 604 may then display the display data via the display 624.

It is noted that the techniques described herein may be embodied in executable instructions stored in a computer readable medium for use by or in connection with a processor-based instruction execution machine, system, apparatus, or device. It will be appreciated by those skilled in the art that, for some embodiments, various types of computer-readable media can be included for storing data. As used herein, a “computer-readable medium” includes one or more of any suitable media for storing the executable instructions of a computer program such that the instruction execution machine, system, apparatus, or device may read (or fetch) the instructions from the computer-readable medium and execute the instructions for carrying out the described embodiments. Suitable storage formats include one or more of an electronic, magnetic, optical, and electromagnetic format. A non-exhaustive list of conventional exemplary computer-readable medium includes: a portable computer diskette; a random-access memory (RAM); a read-only memory (ROM); an erasable programmable read only memory (EPROM); a flash memory device; and optical storage devices, including a portable compact disc (CD), a portable digital video disc (DVD), and the like.

It should be understood that the arrangement of components illustrated in the attached Figures are for illustrative purposes and that other arrangements are possible. For example, one or more of the elements described herein may be realized, in whole or in part, as an electronic hardware component. Other elements may be implemented in software, hardware, or a combination of software and hardware. Moreover, some or all of these other elements may be combined, some may be omitted altogether, and additional components may be added while still achieving the functionality described herein. Thus, the subject matter described herein may be embodied in many different variations, and all such variations are contemplated to be within the scope of the claims.

To facilitate an understanding of the subject matter described herein, many aspects are described in terms of sequences of actions. It will be recognized by those skilled in the art that the various actions may be performed by specialized circuits or circuitry, by program instructions being executed by one or more processors, or by a combination of both. The description herein of any sequence of actions is not intended to imply that the specific order described for performing that sequence must be followed. All methods described herein may be performed in any suitable order unless otherwise indicated herein or otherwise clearly contradicted by context.

The use of the terms “a” and “an” and “the” and similar references in the context of describing the subject matter (particularly in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. Furthermore, the foregoing description is for the purpose of illustration only, and not for the purpose of limitation, as the scope of protection sought is defined by the claims as set forth hereinafter together with any equivalents thereof. The use of any and all examples, or exemplary language (e.g., “such as”) provided herein, is intended merely to better illustrate the subject matter and does not pose a limitation on the scope of the subject matter unless otherwise claimed. The use of the term “based on” and other like phrases indicating a condition for bringing about a result, both in the claims and in the written description, is not intended to foreclose any other conditions that bring about that result. No language in the specification should be construed as indicating any non-claimed element as essential to the practice of the invention as claimed.

what is claimed is:

1. A system for processing parameters, comprising:
a memory storing a block array including the parameters organized into blocks, each block including a subset of the parameters; and
a processor coupled to the memory, wherein the processor encodes the block array by:
normalizing the parameters using a scale factor for the block array;
for each block, mapping each normalized parameter in the block to quantized values stored in each codebook of a plurality of codebooks to determine a set of quantization errors, wherein each quantization error in the set of quantization errors is associated with a different one of the codebooks in the plurality of codebooks;
for each block, identifying the codebook in the plurality of codebooks that is associated with a minimum quantization error in the set of quantization errors for the block as a selected codebook for the block; and
encoding the normalized parameters in each block to a bitwidth using the selected codebook for the block to produce an encoded block array.

2. The system of claim 1, wherein the encoded block array comprises the scale factor and encoded versions of each block, wherein each encoded version includes an identifier for the selected codebook for the block and indices corresponding to entries of the selected codebook where quantized versions of the subset of parameters in the encoded version are stored.

3. The system of claim 1, wherein at least one codebook in the plurality of codebooks is implemented as a read-only-memory.

4. The system of claim 1, wherein at least one codebook in the plurality of codebooks is implemented as a read-write memory.

5. The system of claim 1, wherein each quantization error in the set of quantization errors for each block is computed as one of a sum of pre-computed errors of the quantized values stored in a different one of the codebooks in the plurality of codebooks mapped to the normalized parameters in the block or a sum of pre-computed squared errors of the quantized values stored in the different one of the codebooks in the plurality of codebooks mapped to the normalized parameters in the block.

6. The system of claim 1, wherein the quantization errors in the set of quantization errors for each block are determined using a look-up table that stores an error for each possible value of the normalized parameters stored in the plurality of codebooks.

7. The system of claim 6, wherein at least one of the look-up tables is implemented as a read-only-memory or read-write memory.

8. The system of claim 1, wherein the sets of quantization errors for the blocks are determined in parallel.

9. The system of claim 1, wherein the selected codebooks for the blocks are identified in parallel.

10. The system of claim 1, wherein encoding the normalized parameters in each block comprises, for each block:
encoding the normalized parameters in the block using each of the codebooks to produce sets of codebook encoded parameters for the block; and
selecting one set of the codebook encoded parameters corresponding to the selected codebook for the block as the encoded parameters included in the encoded block array.

11. The system of claim 1, further comprising processing the encoded block array by performing operations at the bitwidth to produce an output value.

12. The system of claim 1, wherein the encoded block array includes parameters comprising encoded weights for a neural network model and a second encoded block array includes blocks of encoded activations.

13. The system of claim 12, further comprising multiple quantized dot-product units wherein each quantized dot-product unit computes partial products using quantized activation block arrays and quantized weight block arrays.

14. The system of claim 13, further comprising:
a first block array decoder coupled to a first input of each one of the multiple quantized dot-product units to generate the quantized activation block array from the second encoded block array; and
at least a second block decoder coupled to the multiple quantized dot-product units to generate the quantized weight block arrays for each one of the multiple quantized dot-product units from the encoded block array and at least one additional encoded block array.

15. A method for processing parameters, comprising:
storing a block array including the parameters organized into blocks in a memory, each block including a subset of the parameters; and
encoding the block array by:
normalizing the parameters using a scale factor for the block array;
for each block, mapping each normalized parameter in the block to quantized values stored in each codebook of a plurality of codebooks to determine a set of quantization errors, wherein each quantization error in the set of quantization errors is associated with a different one of the codebooks in the plurality of codebooks;
for each block, identifying the codebook in the plurality of codebooks that is associated with a minimum quantization error in the set of quantization errors for the block as a selected codebook for the block; and
encoding the normalized parameters in each block to a bitwidth using the selected codebook for the block to produce an encoded block array.

16. The method of claim 15, wherein the encoded block array comprises the scale factor and encoded versions of each block, wherein each encoded version includes an identifier for the selected codebook for the block and indices corresponding to entries of the selected codebook where quantized versions of the subset of parameters in the encoded version are stored.

17. The method of claim 15, wherein at least one of the steps of storing and encoding is performed on a server or in a data center and the encoded block array is streamed to a user device.

18. The method of claim 15, wherein at least one of the steps of storing and encoding is performed within a cloud computing environment.

19. The method of claim 15, wherein at least one of the steps of storing and encoding is performed for training, testing, or certifying a neural network model employed in a machine, robot, or autonomous vehicle.

20. The method of claim 15, wherein at least one of the steps of storing and encoding is performed on a virtual machine comprising a portion of a graphics processing unit.

21. The method of claim 15, wherein at least one of the steps of storing and encoding is implemented to include advanced error correction, fault-tolerance, and self-healing capabilities.
